(19) United States
(12) Patent Application Publication
(10) Pub. No.: US 2026/0344040 A1
(43) Pub. Date: Oct. 29, 2026

(54) SEMICONDUCTOR DEVICE INCLUDING SILICIDE LAYERS

(71) Applicant: Samsung Electronics Co., Ltd., Suwon-si (KR)

(72) Inventors: Seung Seok Han, Suwon-si (KR); Sun Jung Lee, Suwon-si (KR); Dong Ju Kim, Suwon-si (KR); Do Sun Lee, Suwon-si (KR); Seung Keun Cha, Suwon-si (KR)

(21) Appl. No.: 19/408,948

(22) Filed: Dec. 4, 2025

(30) Foreign Application Priority Data
Apr. 28, 2025 (KR) 10-2025-0055295

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

A semiconductor device includes: a substrate; an active pattern on an upper surface of the substrate; gate electrode on the active pattern; a bottom source/drain region on the gate electrode; an upper source/drain region on the gate electrode; an interlayer insulating layer covering the upper source/drain region; a source/drain contact on the gate electrode, the source/drain contact penetrating the interlayer insulating layer and the upper source/drain region in the vertical direction, at least a portion of the source/drain contact extending into the bottom source/drain region, the source/drain contact connected to the bottom source/drain region and the upper source/drain region; a lower silicide layer between the bottom source/drain region and the source/drain contact, the lower silicide layer including a first metal silicide; and an upper silicide layer between the upper source/drain region and the source/drain contact, the upper silicide layer including a second metal silicide different from the first metal silicide.

### CROSS-REFERENCE TO RELATED APPLICATION

This application claims priority from Korean Patent Application No. 10-2025-0055295 filed on Apr. 28, 2025 in the Korean Intellectual Property Office, and all the benefits accruing therefrom under 35 U.S.C. 119, the contents of which in its entirety are herein incorporated by reference.

### BACKGROUND

As integrated circuit technology continues to evolve, increasing device density remains a challenge. This has led to the exploration of advanced transistor architectures that offer improved scalability and performance.

### SUMMARY

As one of the scaling techniques to increase the density of integrated circuit devices, multi-gate transistors may be used, in which a fin-shaped or nanowire-shaped silicon body may be formed on a substrate, and gates may be formed on the surface of the silicon body.

Since multi-gate transistors utilize a three-dimensional channel, scaling may be facilitated. Additionally, the current control capability may be improved without increasing the gate length of the multi-gate transistor. Furthermore, the SCE (short channel effect), in which the potential of the channel region is influenced by the drain voltage, may be effectively suppressed.

The present disclosure provides a semiconductor device having improved electrical characteristics by including different materials in a lower silicide layer and an upper silicide layer in a structure in which an NMOS transistor is stacked on a PMOS transistor.

Implementations of the present disclosure are not limited to those mentioned above, and other aspects not explicitly described may be clearly understood by those skilled in the art from the following description.

An aspect of the present disclosure provides a semiconductor device that includes a substrate, an active pattern extending in a first horizontal direction on an upper surface of the substrate, a gate electrode extending in a second horizontal direction different from the first horizontal direction on the active pattern, a bottom source/drain region disposed on one side of the gate electrode on the active pattern, an upper source/drain region disposed on the one side of the gate electrode, the upper source/drain region spaced apart from the bottom source/drain region in a vertical direction, an interlayer insulating layer covering the upper source/drain region, a source/drain contact disposed on the one side of the gate electrode, the source/drain contact penetrating the interlayer insulating layer and the upper source/drain region in the vertical direction, at least a portion of the source/drain contact extending into the bottom source/drain region, the source/drain contact electrically connected to each of the bottom source/drain region and the upper source/drain region, a lower silicide layer disposed along an interface between the bottom source/drain region and the source/drain contact, the lower silicide layer including a first metal silicide, and an upper silicide layer disposed along an interface between the upper source/drain region and the source/drain contact, the upper silicide layer including a second metal silicide different from the first metal silicide.

Another aspect of the present disclosure provides a semiconductor device that includes a substrate, an active pattern extending in a first horizontal direction on an upper surface of the substrate, a plurality of bottom nanosheets spaced apart from each other in a vertical direction and stacked on the active pattern, a nanosheet isolation layer disposed on the plurality of bottom nanosheets, the nanosheet isolation layer including an insulating material, a plurality of upper nanosheets spaced apart from each other in the vertical direction and stacked on an upper surface of the nanosheet isolation layer, a bottom source/drain region being in contact with sidewalls of the plurality of bottom nanosheets in the first horizontal direction, an upper source/drain region spaced apart from the bottom source/drain region in the vertical direction, the upper source/drain region being in contact with sidewalls of the plurality of upper nanosheets in the first horizontal direction, a source/drain contact penetrating the upper source/drain region in the vertical direction, at least a portion of the source/drain contact extending into the bottom source/drain region, the source/drain contact electrically connected to each of the bottom source/drain region and the upper source/drain region, a lower silicide layer disposed along an interface between the bottom source/drain region and the source/drain contact, the lower silicide layer including a first metal silicide, and an upper silicide layer disposed along an interface between the upper source/drain region and the source/drain contact, the upper silicide layer including a second metal silicide different from the first metal silicide.

An aspect of the present disclosure provides a semiconductor device that includes a substrate, an active pattern extending in a first horizontal direction on an upper surface of the substrate, a plurality of bottom nanosheets spaced apart from each other in a vertical direction and stacked on the active pattern, a nanosheet isolation layer disposed on the plurality of bottom nanosheets, the nanosheet isolation layer including an insulating material, a plurality of upper nanosheets spaced apart from each other in the vertical direction and stacked on an upper surface of the nanosheet isolation layer, a gate electrode extending in a second horizontal direction different from the first horizontal direction on the active pattern, the gate electrode surrounding each of the plurality of bottom nanosheets, the nanosheet isolation layer and the plurality of upper nanosheets, a bottom source/drain region disposed on one side of the gate electrode on the active pattern, the bottom source/drain region being in contact with sidewalls of the plurality of bottom nanosheets in the first horizontal direction, an upper source/drain region disposed on the one side of the gate electrode, the upper source/drain region spaced apart from the bottom source/drain region in the vertical direction, the upper source/drain region being in contact with sidewalls of the plurality of upper nanosheets in the first horizontal direction, a first interlayer insulating layer disposed between the bottom source/drain region and the upper source/drain region, a second interlayer insulating layer disposed on an upper surface of the upper source/drain region, a source/drain contact penetrating the second interlayer insulating layer, the upper source/drain region and the first interlayer insulating layer in the vertical direction, at least a portion of the source/drain contact extending into the bottom source/drain region, the source/drain contact separating the upper source/drain region in the first horizontal direction, the source/drain contact electrically connected to each of the bottom source/drain region and the upper source/drain region, sidewalls of the source/drain contact having a stepped profile in the first horizontal direction in the first interlayer insulating layer, a lower silicide layer disposed along an interface between the bottom source/drain region and the source/drain contact, the lower silicide layer including a first metal silicide, and an upper silicide layer disposed along an interface between the upper source/drain region and the source/drain contact, the upper silicide layer including a second metal silicide different from the first metal silicide, where the upper silicide layer comprises a first layer being in contact with the source/drain contact, the first layer including a nitrided form of the second metal silicide, and a second layer being in contact with the upper source/drain region, the second layer including the second metal silicide.

### BRIEF DESCRIPTION OF THE DRAWINGS

FIG. 1 is a schematic layout diagram illustrating an example of a semiconductor device.

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIGS. 5 to 38 are intermediate stage diagrams illustrating an example method for fabricating a semiconductor device.

FIGS. 39 and 40 are cross-sectional views illustrating an example of a semiconductor device.

FIG. 41 is a cross-sectional view illustrating an example of a semiconductor device.

FIG. 42 is a cross-sectional view illustrating an example of a semiconductor device.

FIG. 43 is a cross-sectional view illustrating an example of a semiconductor device.

FIG. 44 is a schematic layout diagram illustrating an example of a semiconductor device.

FIG. 45 is a cross-sectional view taken along line D-D′ of FIG. 44.

### DETAILED DESCRIPTION

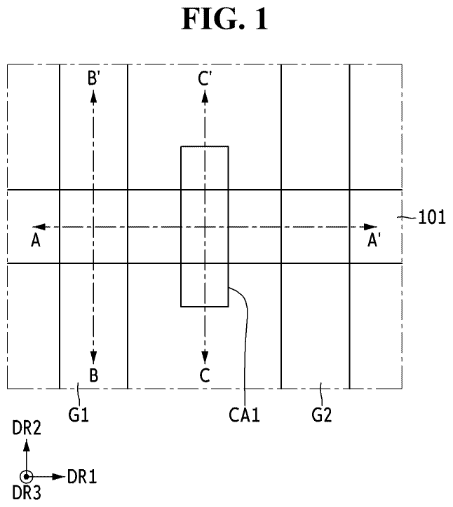

Hereinafter, a semiconductor device according to some implementations of the present disclosure will be described with reference to FIGS. 1 to 4.

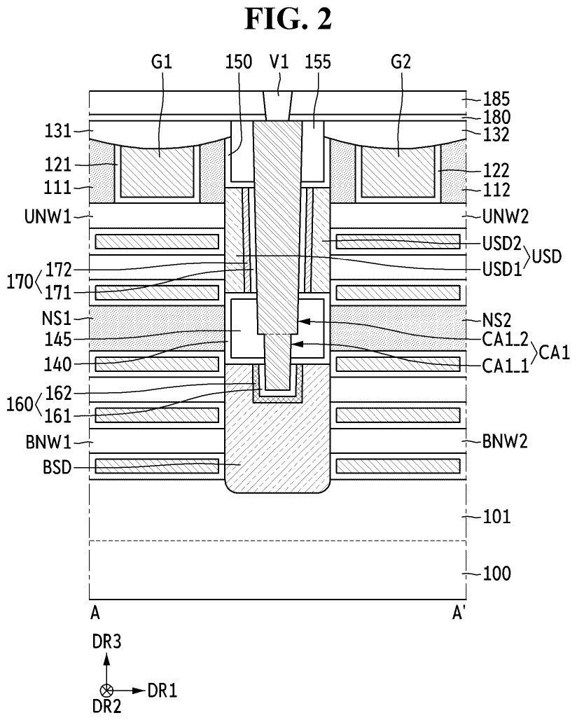

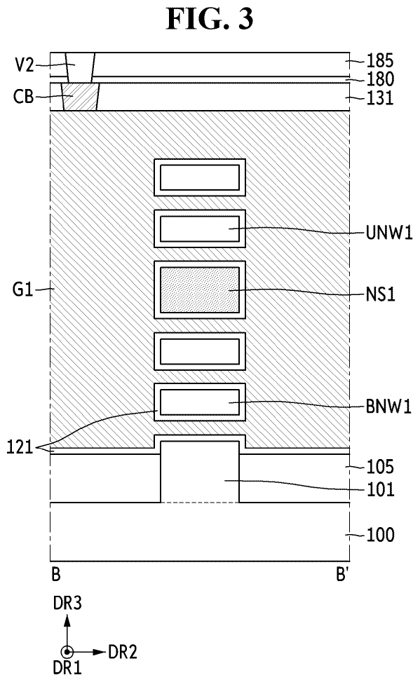

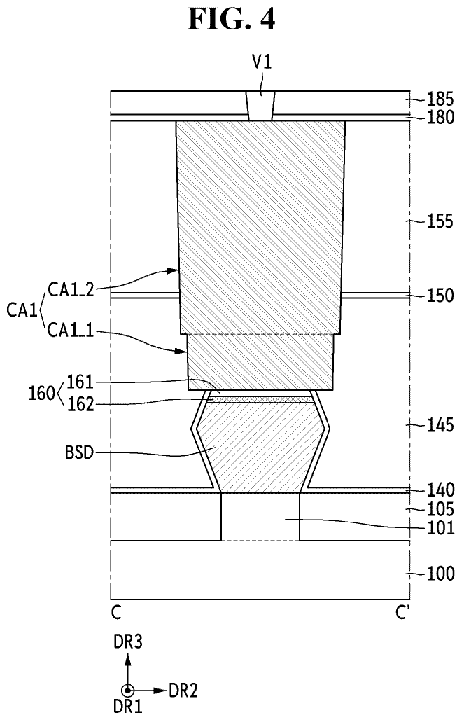

FIG. 1 is a schematic layout diagram for explaining a semiconductor device according to some implementations of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring to FIGS. 1 to 4, a semiconductor device according to some implementations of the present disclosure may include a substrate 100, an active pattern 101, a field insulating layer 105, first and second pluralities of bottom nanosheets BNW1, BNW2, first and second nanosheet isolation layers NS1, NS2, first and second pluralities of upper nanosheets UNW1, UNW2, first and second gate electrodes G1, G2, first and second gate spacers 111, 112, first and second gate insulating layers 121, 122, first and second capping patterns 131, 132, a bottom source/drain region BSD, an upper source/drain region USD, a first etching stop layer 140, a first interlayer insulating layer 145, a second etching stop layer 150, a second interlayer insulating layer 155, a source/drain contact CA1, a lower silicide layer 160, an upper silicide layer 170, a gate contact CB, a third etching stop layer 180, a third interlayer insulating layer 185, and first and second vias V1, V2.

The substrate 100 may be a silicon substrate or a silicon-on-insulator (SOI) substrate. In some implementations, the substrate 100 may include silicon germanium, silicon germanium on insulator (SGOI), indium antimonide, lead telluride compounds, indium arsenide, indium phosphide, gallium arsenide, or gallium antimonide. Hereinafter, a first horizontal direction DR1 and a second horizontal direction DR2 may be defined as directions parallel to an upper surface of the substrate 100. The second horizontal direction DR2 may be defined as a direction different from the first horizontal direction DR1. A vertical direction DR3 may be defined as a direction perpendicular to both the first horizontal direction DR1 and the second horizontal direction DR2. That is, the vertical direction DR3 may be defined as a direction perpendicular to the upper surface of the substrate 100.

The active pattern 101 may protrude from the substrate 100 in the vertical direction DR3. The active pattern 101 may extend in the first horizontal direction DR1. The active pattern 101 may be a part of the substrate 100 or may include an epitaxial layer grown from the substrate 100. For example, the active pattern 101 may include the same material as the substrate 100. The field insulating layer 105 may be disposed on the upper surface of the substrate 100. The field insulating layer 105 may surround sidewalls of the active pattern 101. For example, an upper surface of the field insulating layer 105 may be formed higher than an upper surface of the active pattern 101. For example, the field insulating layer 105 may include an oxide layer, a nitride layer, an oxynitride layer, or a combination thereof.

The first plurality of bottom nanosheets BNW1 may be disposed on the active pattern 101. The first plurality of bottom nanosheets BNW1 may include a plurality of nanosheets spaced apart from each other in the vertical direction DR3 and stacked on the active pattern 101. For example, a bottom surface of a lowermost nanosheet of the first plurality of bottom nanosheets BNW1 may be spaced apart from the upper surface of the active pattern 101 in the vertical direction DR3. The second plurality of bottom nanosheets BNW2 may be disposed on the active pattern 101. The second plurality of bottom nanosheets BNW2 may be spaced apart from the first plurality of bottom nanosheets BNW1 in the first horizontal direction DR1. The second plurality of bottom nanosheets BNW2 may include a plurality of nanosheets spaced apart from each other in the vertical direction DR3 and stacked on the active pattern 101. For example, a bottom surface of a lowermost nanosheet of the second plurality of bottom nanosheets BNW2 may be spaced apart from the upper surface of the active pattern 101 in the vertical direction DR3.

In FIGS. 2 and 3, the first and second pluralities of bottom nanosheets BNW1 and BNW2 are shown as including two nanosheets stacked in the vertical direction DR3. In some implementations, each of the first and second pluralities of bottom nanosheets BNW1, BNW2 may include three or more nanosheets stacked in the vertical direction DR3. For example, each of the first and second pluralities of bottom nanosheets BNW1, BNW2 may include silicon (Si). In some implementations, each of the first and second pluralities of bottom nanosheets BNW1, BNW2 may include silicon germanium (SiGe).

The first nanosheet isolation layer NS1 may be disposed on the first plurality of bottom nanosheets BNW1. For example, the first nanosheet isolation layer NS1 may be spaced apart from the upper surface of the uppermost nanosheet of the first plurality of bottom nanosheets BNW1 in the vertical direction DR3. The second nanosheet isolation layer NS2 may be disposed on the second plurality of bottom nanosheets BNW2. The second nanosheet isolation layer NS2 may be spaced apart from the first nanosheet isolation layer NS1 in the first horizontal direction DR1. For example, the second nanosheet isolation layer NS2 may be spaced apart from the upper surface of the uppermost nanosheet of the second plurality of bottom nanosheets BNW2 in the vertical direction DR3. Each of the first and second nanosheet isolation layers NS1, NS2 may include an insulating material. For example, each of the first and second nanosheet isolation layers NS1, NS2 may include at least one of silicon nitride (SiN), silicon oxycarbonitride (SiOCN), silicon boron carbonitride (SiBCN), silicon carbonitride (SiCN), silicon oxynitride (SiON), and combinations thereof.

The first plurality upper nanosheets UNW1 may be disposed on an upper surface of the first nanosheet isolation layer NS1. The first plurality upper nanosheets UNW1 may include a plurality of nanosheets spaced apart from each other in the vertical direction DR3 and stacked on the upper surface of the first nanosheet isolation layer NS1. For example, the bottom surface of the lowermost nanosheet of the first plurality of upper nanosheets UNW1 may be spaced apart from the upper surface of the first nanosheet isolation layer NS1 in the vertical direction DR3. The second plurality of upper nanosheets UNW2 may be disposed on an upper surface of the second nanosheet isolation layer NS2. The second plurality of upper nanosheets UNW2 may be spaced apart from the first plurality of upper nanosheets UNW1 in the first horizontal direction DR1. The second plurality of upper nanosheets UNW2 may include a plurality of nanosheets spaced apart from each other in the vertical direction DR3 and stacked on the upper surface of the second nanosheet isolation layer NS2. For example, a bottom surface of a lowermost nanosheet of the second plurality of upper nanosheets UNW2 may be spaced apart from the upper surface of the second nanosheet isolation layer NS2 in the vertical direction DR3.

Although FIGS. 2 and 3 illustrate that each of the first and second pluralities of upper nanosheets UNW1, UNW2 includes two nanosheets stacked in the vertical direction DR3, in some implementations, each of the first and second pluralities of upper nanosheets UNW1, UNW2 may include three or more nanosheets stacked in the vertical direction DR3. For example, each of the first and second pluralities of upper nanosheets UNW1, UNW2 may include silicon (Si). In some implementations, each of the first and second pluralities of upper nanosheets UNW1, UNW2 may include silicon germanium (SiGe).

For example, the sidewall of each of the first plurality of bottom nanosheets BNW1, the first nanosheet isolation layer NS1, and the first plurality of upper nanosheets UNW1 in the first horizontal direction DR1 may be aligned. In addition, the sidewall of each of the first plurality of bottom nanosheets BNW1, the first nanosheet isolation layer NS1, and the first plurality of upper nanosheets UNW1 in the second horizontal direction DR2 may be aligned. For example, the sidewall of each of the second plurality of bottom nanosheets BNW2, the second nanosheet isolation layer NS2, and the second plurality of upper nanosheets UNW2 in the first horizontal direction DR1 may be aligned. In addition, the sidewall of each of the second plurality of bottom nanosheets BNW2, the second nanosheet isolation layer NS2, and the second plurality of upper nanosheets UNW2 in the second horizontal direction DR2 may be aligned.

The first gate electrode G1 may extend in the second horizontal direction DR2 on the active pattern 101. For example, the first gate electrode G1 may surround each of the first plurality of bottom nanosheets BNW1, the first nanosheet isolation layer NS1, and the first plurality of upper nanosheets UNW1. In some implementations, the first gate electrode G1 may include a first lower gate electrode and a first upper gate electrode that are spaced apart from each other in the vertical direction DR3. In this case, the first lower gate electrode may surround a portion of the first plurality of bottom nanosheets BNW1 and the first nanosheet isolation layer NS1, and the first upper gate electrode may surround another portion of the first nanosheet isolation layer NS1 and the first plurality of upper nanosheets UNW1.

The second gate electrode G2 may extend in the second horizontal direction DR2 on the active pattern 101. The second gate electrode G2 may be spaced apart from the first gate electrode G1 in the first horizontal direction DR1. For example, the second gate electrode G2 may surround each of the second plurality of bottom nanosheets BNW2, the second nanosheet isolation layer NS2, and the second plurality of upper nanosheets UNW2. In some implementations, the second gate electrode G2 may include a second lower gate electrode and a second upper gate electrode that are spaced apart from each other in the vertical direction DR3. In this case, the second lower gate electrode may surround a portion of the second plurality of bottom nanosheets BNW2 and the second nanosheet isolation layer NS2, and the second upper gate electrode may surround another portion of the second nanosheet isolation layer NS2 and the second plurality of upper nanosheets UNW2.

Each of the first and second gate electrodes G1, G2 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. Each of the first and second gate electrodes G1, G2 may further include a conductive metal oxide, a conductive metal oxynitride, or an oxidized form of any of the aforementioned materials.

The first gate spacer 111 may extend along both sidewalls of the first gate electrode G1 in the second horizontal direction DR2, on the upper surface of the uppermost nanosheet of the first plurality of upper nanosheets UNW1 and on the upper surface of the field insulating layer 105. The second gate spacer 112 may extend along both sidewalls of the second gate electrode G2 in the second horizontal direction DR2, on the upper surface of the uppermost nanosheet of the second plurality of upper nanosheets UNW2 and on the upper surface of the field insulating layer 105. For example, each of the first and second gate spacers 111, 112 may include at least one of silicon nitride (SiN), silicon oxynitride (SiON), silicon oxide (SiO₂), silicon oxycarbonitride(SiOCN), silicon boron nitride (SiBN), silicon oxyboron nitride (SiOBN), silicon oxycarbide (SiOC), or combinations thereof.

The first gate insulating layer 121 may be disposed between the first gate electrode G1 and the field insulating layer 105. The first gate insulating layer 121 may also be disposed between the first gate electrode G1 and the first gate spacer 111. The first gate insulating layer 121 may be disposed between the first gate electrode G1 and the first plurality of bottom nanosheets BNW1. The first gate insulating layer 121 may also be disposed between the first gate electrode G1 and the first nanosheet isolation layer NS1. The first gate insulating layer 121 may be disposed between the first gate electrode G1 and the first plurality of upper nanosheets UNW1. Additionally, the first gate insulating layer 121 may be disposed on both sidewalls of the first gate electrode G1 in the first horizontal direction DR1.

The second gate insulating layer 122 may be disposed between the second gate electrode G2 and the field insulating layer 105. The second gate insulating layer 122 may also be disposed between the second gate electrode G2 and the second gate spacer 112. The second gate insulating layer 122 may be disposed between the second gate electrode G2 and the second plurality of bottom nanosheets BNW2. The second gate insulating layer 122 may also be disposed between the second gate electrode G2 and the second nanosheet isolation layer NS2. The second gate insulating layer 122 may be disposed between the second gate electrode G2 and the second plurality of upper nanosheets UNW2. Additionally, the second gate insulating layer 122 may be disposed on both sidewalls of the second gate electrode G2 in the first horizontal direction DR1.

Each of the first and second gate insulating layers 121, 122 may include at least one of silicon oxide, silicon oxynitride, silicon nitride, or a high-k dielectric material having a dielectric constant greater than that of silicon oxide. The high-k dielectric material may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanate, barium titanate, strontium titanate, yttrium oxide, aluminum oxide, lead scandium tantalate, or lead zinc niobate.

The semiconductor device according to some implementations may include an NC (Negative Capacitance) FET that utilizes a negative capacitor. For example, each of the first and second gate insulating layers 121, 122 may include a ferroelectric material layer having ferroelectric properties and a paraelectric material layer having paraelectric properties.

The ferroelectric material layer may have a negative capacitance, while the paraelectric material layer may have a positive capacitance. For example, when two or more capacitors are connected in series and each capacitor has a positive capacitance, the total capacitance becomes less than that of each individual capacitor. On the other hand, if at least one of the capacitances of two or more capacitors connected in series has a negative capacitance, the total capacitance may be positive and greater than the absolute value of each individual capacitance.

When the ferroelectric material layer having a negative capacitance is connected in series with the paraelectric material layer having a positive capacitance, the total capacitance value of the ferroelectric material layer and the paraelectric material layer connected in series may increase. By utilizing the increase in total capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) combined with oxygen (O).

The ferroelectric material layer may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material the ferroelectric material layer contains, the type of dopant contained in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may contain about 3 to 8 at % (atomic %) of aluminum. In this case, the ratio of the dopant may be the ratio of aluminum to the sum of hafnium and aluminum.

If the dopant is silicon (Si), the ferroelectric material layer may contain 2 to 10 at % of silicon. If the dopant is yttrium (Y), the ferroelectric material layer may contain 2 to 10 at % of yttrium. If the dopant is gadolinium (Gd), the ferroelectric material layer may contain 1 to 7 at % of gadolinium. If the dopant is zirconium (Zr), the ferroelectric material layer may contain 50 to 80 at % of zirconium.

The paraelectric material layer may have paraelectric properties. The paraelectric material layer may include, for example, at least one or more of silicon oxide and metal oxides having a high-k dielectric constant. The metal oxides contained in the paraelectric material layer may include, for example, at least one of hafnium oxide, zirconium oxide, and aluminum oxide.

The ferroelectric material layer and the paraelectric material layer may include the same material. While the ferroelectric material layer may have ferroelectric properties, the paraelectric material layer may not have ferroelectric properties. For example, if both the ferroelectric material layer and the paraelectric material layer contain hafnium oxide, the crystal structure of the hafnium oxide included in the ferroelectric material layer may be different from the crystal structure of the hafnium oxide included in the paraelectric material layer.

The ferroelectric material layer may have a thickness sufficient to exhibit ferroelectric properties. For example, the thickness of the ferroelectric material layer may range from 0.5 to 10 nm. Since the critical thickness for exhibiting ferroelectric properties may vary depending on the ferroelectric material, the thickness of the ferroelectric material layer may also vary depending on the specific ferroelectric material used.

For example, the first and second gate insulating layers 121, 122 may each include a single ferroelectric material layer. In another example, the first and second gate insulating layers 121, 122 may each include a plurality of ferroelectric material layers spaced apart from each other. The first and second gate insulating layers 121, 122 may each have a stacked layer structure in which a plurality of ferroelectric material layers and a plurality of paraelectric material layers are alternately stacked.

The bottom source/drain region BSD may be disposed on one side of the first gate electrode G1 on the active pattern 101. For example, the bottom source/drain region BSD may be disposed between the first gate electrode G1 and the second gate electrode G2 on the active pattern 101. The bottom source/drain region BSD may be disposed between the first plurality of bottom nanosheets BNW1 and the second plurality of bottom nanosheets BNW2 on the active pattern 101. For example, the bottom source/drain region BSD may be in contact with the active pattern 101. In another example, the bottom source/drain region BSD may be in contact with respective sidewalls in the first horizontal direction DR1 of each of the first plurality of bottom nanosheets BNW1 and the second plurality of bottom nanosheets BNW2. For example, the upper surface of the bottom source/drain region BSD may be formed higher than the upper surface of the uppermost nanosheet of the first plurality of bottom nanosheets BNW1 and the upper surface of the uppermost nanosheet of the second plurality of bottom nanosheets BNW2. Additionally, the bottom source/drain region BSD may be in contact with each of the first and second gate insulating layers 121, 122.

The upper source/drain region USD may be disposed on one side of the first gate electrode G1 on the bottom source/drain region BSD. For example, the upper source/drain region USD may be disposed between the first gate electrode G1 and the second gate electrode G2 on the bottom source/drain region BSD. The upper source/drain region USD may be disposed between the first plurality of upper nanosheets UNW1 and the second plurality of upper nanosheets UNW2 on the bottom source/drain region BSD. The upper source/drain region USD may be spaced apart from the bottom source/drain region BSD in a vertical direction DR3. For example, the upper source/drain region USD may be in contact with the sidewall of each of the first plurality of upper nanosheets UNW1 and the second plurality of upper nanosheets UNW2 in the first horizontal direction DR1. For instance, the bottom surface of the upper source/drain region USD may be formed lower than the respective bottom surfaces of the lowermost nanosheet of the first plurality of upper nanosheets UNW1 and the lowermost nanosheet of the second plurality of upper nanosheets UNW2. Additionally, the upper surface of the upper source/drain region USD may be formed higher than the respective upper surfaces of the uppermost nanosheet of the first plurality of upper nanosheets UNW1 and the uppermost nanosheet of the second plurality of upper nanosheets UNW2.

For example, the upper source/drain region USD may be separated in the first horizontal direction DR1 by the source/drain contact CA1. For example, the upper source/drain region USD may include a first portion USD1 and a second portion USD2, which are separated in the first horizontal direction DR1 by the source/drain contact CA1. That is, the second portion USD2 of the upper source/drain region USD may be spaced apart from the first portion USD1 of the upper source/drain region USD in the first horizontal direction DR1. For example, the first portion USD1 of the upper source/drain region USD may be disposed between the first plurality of upper nanosheets UNW1 and the source/drain contact CA1. For example, the second portion USD2 of the upper source/drain region USD may be disposed between the second plurality of upper nanosheets UNW2 and the source/drain contact CA1. For example, the first portion USD1 of the upper source/drain region USD may be in contact with the first plurality of upper nanosheets UNW1, and the second portion USD2 of the upper source/drain region USD may be in contact with the second plurality of upper nanosheets UNW2. For example, the upper source/drain region USD may be in contact with each of the first gate insulating layer 121 and the second gate insulating layer 122.

The first etching stop layer 140 may be disposed on the upper surface of the field insulating layer 105, and on sidewalls and the upper surface of the bottom source/drain region BSD in the second horizontal direction DR2. The first etching stop layer 140 may be disposed on the sidewall of each of the first and second nanosheet isolation layers NS1, NS2 in the first horizontal direction DR1. For example, the first etching stop layer 140 may be formed conformally. For example, the first etching stop layer 140 may be in contact with the field insulating layer 105, the bottom source/drain region BSD, and the first and second nanosheet isolation layers NS1, NS2. For example, the first etching stop layer 140 may be in contact with each of the first and second gate insulating layers 121, 122. For example, the first etching stop layer 140 may include at least one of aluminum oxide, aluminum nitride, hafnium oxide, zirconium oxide, silicon oxide, silicon nitride, silicon oxynitride, and low-k dielectric materials.

The first interlayer insulating layer 145 may be disposed on the first etching stop layer 140. For example, the first interlayer insulating layer 145 may cover the bottom source/drain region BSD on the field insulating layer 105. For example, the first interlayer insulating layer 145 may be disposed between the upper surface of the bottom source/drain region BSD and the bottom surface of the upper source/drain region USD. For example, the first interlayer insulating layer 145 and the second interlayer insulating layer 155 may each include at least one of silicon oxide, silicon nitride, silicon oxynitride, and a low-k material. The low-k material may include, for example, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), polyimide nanofoams such as TOSZ (Tonen SilaZen), FSG (Fluoride Silicate Glass), polypropylene oxide, Carbon Doped Silicon Oxide (CDO), Organo Silicate Glass (OSG), SiLK, Amorphous Fluorinated Carbon, silica aerogels, silica xerogels, mesoporous silica, or combinations thereof.

The second etching stop layer 150 may be disposed on the upper surface of the first interlayer insulating layer 145, the bottom surface and upper surface of the upper source/drain region USD, and the sidewalls of each of the first and second gate spacers 111, 112 in the second horizontal direction DR2. For example, the second etching stop layer 150 may be formed conformally. For example, the second etching stop layer 150 may be in contact with the first interlayer insulating layer 145, the upper source/drain region USD, and the first and second gate spacers 111, 112. For example, the second etching stop layer 150 may include at least one of aluminum oxide, aluminum nitride, hafnium oxide, zirconium oxide, silicon oxide, silicon nitride, silicon oxynitride, and low-k dielectric materials.

The first capping pattern 131 may extend in the second horizontal direction DR2 over each of the first gate spacer 111, the first gate insulating layer 121, and the first gate electrode G1. The second capping pattern 132 may extend in the second horizontal direction DR2 over each of the second gate spacer 112, the second gate insulating layer 122, and the second gate electrode G2. For example, the bottom surfaces of the first and second capping patterns 131, 132 may be in contact with the second etching stop layer 150. In some implementations, the sidewalls of the first and second capping patterns 131, 132 may also be in contact with the second etching stop layer 150. For example, each of the first and second capping patterns 131, 132 may include at least one of silicon nitride (SiN), silicon oxynitride (SiON), silicon oxide (SiO₂), silicon carbonitride (SiCN), silicon oxycarbonitride (SiOCN), or combinations thereof.

The second interlayer insulating layer 155 may be disposed on the second etching stop layer 150. For example, the second interlayer insulating layer 155 may be in contact with the second etching stop layer 150. The second interlayer insulating layer 155 may be disposed on the sidewall of each of the first and second capping patterns 131, 132. The second interlayer insulating layer 155 may cover the upper source/drain region USD. That is, the second interlayer insulating layer 155 may be disposed on the upper surface of the upper source/drain region USD. For example, the upper surface of the second interlayer insulating layer 155 may be formed on the same plane as the upper surfaces of the first and second capping patterns 131, 132. For example, the second interlayer insulating layer 155 may include at least one of silicon oxide, silicon nitride, silicon oxynitride, and low-k dielectric materials.

The source/drain contact CA1 may be disposed on one side of the first gate electrode G1. For example, the source/drain contact CA1 may be disposed between the first gate electrode G1 and the second gate electrode G2. For example, the source/drain contact CA1 may extend in the second horizontal direction DR2. The source/drain contact CA1 may penetrate the second interlayer insulating layer 155, the second etching stop layer 150, the upper source/drain region USD, the first interlayer insulating layer 145, and the first etching stop layer 140 in the vertical direction DR3 and extend into the interior of the bottom source/drain region BSD. That is, at least a portion of the bottom source/drain region BSD may be disposed within the bottom source/drain region BSD. The source/drain contact CA1 may be electrically connected to each of the upper source/drain region USD and the bottom source/drain region BSD.

For example, the upper surface of the source/drain contact CA1 may be formed on the same plane as the upper surface of the second interlayer insulating layer 155. For example, the bottom surface of the source/drain contact CA1 may be formed higher than the bottom surface of the bottom source/drain region BSD. For example, the source/drain contact CA1 may separate the upper source/drain region USD in the first horizontal direction DR1. For example, the width of the upper surface of the source/drain contact CA1 in the first horizontal direction DR1 may be greater than the width of the bottom surface of the source/drain contact CA1 in the first horizontal direction DR1. For example, within the first interlayer insulating layer 145, the sidewalls of the source/drain contact CA1 in the first horizontal direction DR1 may have a stepped profile. Additionally, within the first interlayer insulating layer 145, the sidewalls of the source/drain contact CA1 in the second horizontal direction DR2 may also have a stepped profile.

For example, the source/drain contact CA1 may include a first portion CA1_1 and a second portion CA1_2 disposed on the upper surface of the first portion CA1_1. At least a portion of the first portion CA1_1 of the source/drain contact CA1 may extend into the bottom source/drain region BSD. For example, the upper surface of the first portion CA1_1 of the source/drain contact CA1 may be formed higher than the upper surface of the bottom source/drain region BSD. For example, the sidewall of the first portion CA1_1 of the source/drain contact CA1 in the first horizontal direction DR1 may be in contact with the first interlayer insulating layer 145. Additionally, the sidewall of the first portion CA1_1 of the source/drain contact CA1 in the second horizontal direction DR2 may be in contact with the first interlayer insulating layer 145.

For example, the bottom surface of the second portion CA1_2 of the source/drain contact CA1 may be in contact with the upper surface of the first portion CA1_1 of the source/drain contact CA1. For example, the second portion CA1_2 of the source/drain contact CA1 may penetrate the second interlayer insulating layer 155, the second etching stop layer 150, and the upper source/drain region USD in the vertical direction DR3 and extend into the first interlayer insulating layer 145. For example, the bottom surface of the second portion CA1_2 of the source/drain contact CA1 may be formed lower than the bottom surface of the upper source/drain region USD. For example, the sidewall of the second portion CA1_2 of the source/drain contact CA1 in the first horizontal direction DR1 may be in contact with the first interlayer insulating layer 145. Additionally, the sidewall of the second portion CA1_2 of the source/drain contact CA1 in the second horizontal direction DR2 may be in contact with the first interlayer insulating layer 145.

For example, the width of the upper surface of the first portion CA1_1 of the source/drain contact CA1 in the first horizontal direction DR1 may be smaller than the width of the bottom surface of the second portion CA1_2 of the source/drain contact CA1 in the first horizontal direction DR1. Additionally, the width of the upper surface of the first portion CA1_1 of the source/drain contact CA1 in the second horizontal direction DR2 may be smaller than the width of the bottom surface of the second portion CA1_2 of the source/drain contact CA1 in the second horizontal direction DR2. That is, within the first interlayer insulating layer 145, the sidewall where the first portion CA1_1 and the second portion CA1_2 of the source/drain contact CA1 are in contact with each other may have a stepped profile. For example, the source/drain contact CA1 may include a conductive material.

The lower silicide layer 160 may be disposed along an interface between the bottom source/drain region BSD and the source/drain contact CA1. For example, the lower silicide layer 160 may include a first metal silicide. The first metal silicide may include any one of scandium silicide (SiSc), erbium silicide (SiEr), lanthanum silicide (SiLa), yttrium silicide (SiY), hafnium silicide (SiHf), or zirconium silicide (SiZr). For example, the lower silicide layer 160 may include a first layer 161 and a second layer 162.

For example, the first layer 161 of the lower silicide layer 160 may be in contact with the source/drain contact CA1. For example, the first layer 161 of the lower silicide layer 160 may include a nitrided form of the first metal silicide. That is, the first layer 161 of the lower silicide layer 160 may include any one of SiScN, SiErN, SiLaN, SiYN, SiHfN, or SiZrN. For example, the second layer 162 of the lower silicide layer 160 may be disposed between the first layer 161 of the lower silicide layer 160 and the bottom source/drain region BSD. The second layer 162 of the lower silicide layer 160 may be in contact with the bottom source/drain region BSD. For example, the second layer 162 of the lower silicide layer 160 may include the first metal silicide.

The upper silicide layer 170 may be disposed along an interface between the upper source/drain region USD and the source/drain contact CA1. For example, the upper silicide layer 170 may include a second metal silicide different from the first metal silicide. For example, the second metal silicide may include any one of molybdenum silicide (SiMo), antimony silicide (SiSb), ruthenium silicide (SiRu), or platinum silicide (SiPt). For example, the upper silicide layer 170 may include a first layer 171 and a second layer 172. For example, the bottom surface of the upper silicide layer 170 may be formed on the same plane as the bottom surface of the upper source/drain region USD. In addition, the upper surface of the upper silicide layer 170 may be formed on the same plane as the upper surface of the upper source/drain region USD.

For example, the first layer 171 of the upper silicide layer 170 may be in contact with the source/drain contact CA1. For example, the first layer 171 of the upper silicide layer 170 may include a nitrided form of the second metal silicide. That is, the first layer 171 of the upper silicide layer 170 may include any one of SiMoN, SiSbN, SiRuN, or SiPtN. For example, the second layer 172 of the upper silicide layer 170 may be disposed between the first layer 171 of the upper silicide layer 170 and the upper source/drain region USD. The second layer 172 of the upper silicide layer 170 may be in contact with the upper source/drain region USD. For example, the second layer 172 of the upper silicide layer 170 may include the second metal silicide.

The gate contact CB may penetrate the first capping pattern 131 in the vertical direction DR3 to be connected to the first gate electrode G1. The gate contact CB may be electrically connected to the first gate electrode G1. The gate contact CB may include a conductive material. The third etching stop layer 180 may be disposed on the upper surfaces of the source/drain contact CA1, the first and second capping patterns 131, 132, the gate contact CB, and the second interlayer insulating layer 155. In FIGS. 2 to 4, the third etching stop layer 180 is shown as being formed as a single layer. In some implementations, the third etching stop layer 180 may be formed as a multi-layer structure. For example, the third etching stop layer 180 may include at least one of aluminum oxide, aluminum nitride, hafnium oxide, zirconium oxide, silicon oxide, silicon nitride, silicon oxynitride, and low-k dielectric materials.

The third interlayer insulating layer 185 may be disposed on the third etching stop layer 180. For example, the third interlayer insulating layer 185 may include at least one of silicon oxide, silicon nitride, silicon oxynitride, and low-k dielectric materials. A first via V1 may penetrate the third interlayer insulating layer 185 and the third etching stop layer 180 in the vertical direction DR3 to be connected to the source/drain contact CA1. A second via V2 may penetrate the third interlayer insulating layer 185 and the third etching stop layer 180 in the vertical direction DR3 to be connected to the gate contact CB. Each of the first via V1 and the second via V2 may include a conductive material.

For example, the first and second pluralities of bottom nanosheets BNW1, BNW2, the first and second gate electrodes G1, G2, and the bottom source/drain region BSD may form a PMOS transistor. For example, the first and second pluralities of upper nanosheets UNW1, UNW2, the first and second gate electrodes G1, G2, and the upper source/drain region USD may form an NMOS transistor. That is, the semiconductor device according to some implementations of the present disclosure has a structure in which the NMOS transistor is stacked in the vertical direction DR3 on the PMOS transistor.

For example, when the lower silicide layer formed in the PMOS transistor and the upper silicide layer formed in the NMOS transistor are formed through the same fabrication process, the lower silicide layer and the upper silicide layer contain the same material. In such a case, the material of each of the lower silicide layer and the upper silicide layer is a material having a resistance value applicable to both the PMOS transistor and the NMOS transistor. That is, when the lower and upper silicide layers contain the same material, there may be a problem where the efficiency of the electrical characteristics of the semiconductor device is relatively reduced.

In some implementations of the present disclosure, the semiconductor device may include the lower silicide layer 160 formed in the PMOS transistor and the upper silicide layer 170 formed in the NMOS transistor, which may be formed through different fabrication processes. As a result, the lower silicide layer 160 and the upper silicide layer 170 may include different materials. That is, in in the semiconductor device according to some implementations of the present disclosure, the lower silicide layer 160 may include a material having a low resistance value in the PMOS transistor, and the upper silicide layer 170 may include a material having a low resistance value in the NMOS transistor. Accordingly, in some implementations of the present disclosure, the efficiency of the electrical characteristics of the semiconductor device may be relatively enhanced.

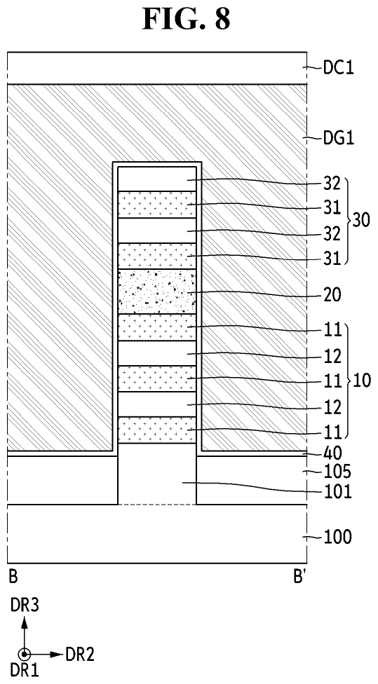

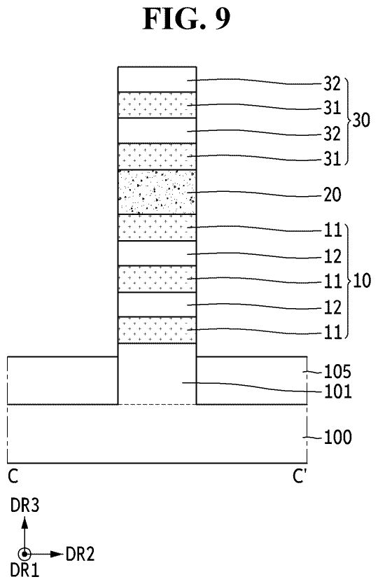

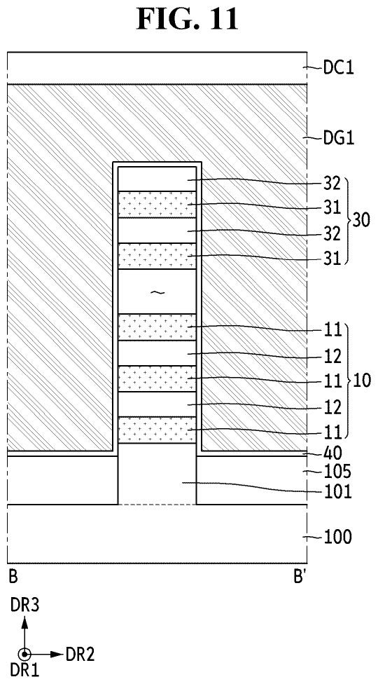

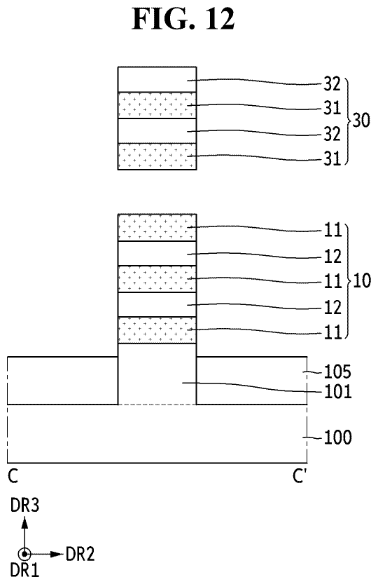

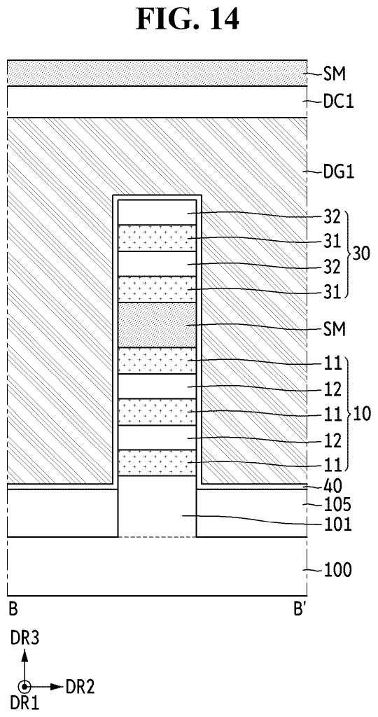

Hereinafter, a method for fabricating a semiconductor device according to some implementations of the present disclosure will be described with reference to FIGS. 2 to 38.

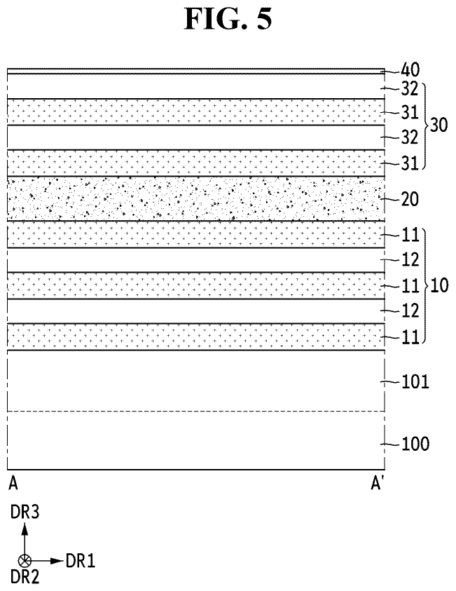

FIGS. 5 to 38 are intermediate stage diagrams for explaining a method for fabricating the semiconductor device according to some implementations of the present disclosure.

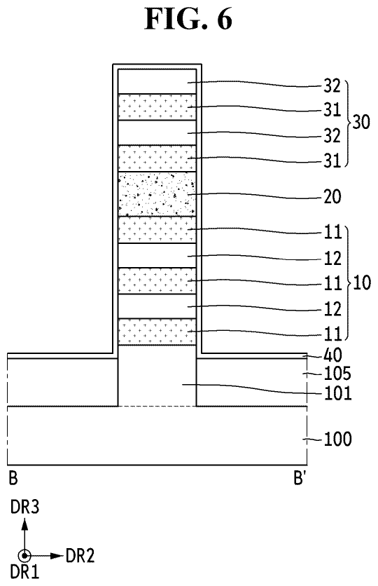

Referring to FIGS. 5 and 6, a first stacked structure 10, an isolation material layer 20, and a second stacked structure 30 may be sequentially stacked on the upper surface of the substrate 100. For example, the first stacked structure 10 may be formed on the upper surface of the substrate 100. The first stacked structure 10 may include first sacrificial layers 11 and first semiconductor layers 12 alternately stacked on the upper surface of the substrate 100. For example, the first sacrificial layers 11 may be formed on both a lowermost portion and an uppermost portion of the first stacked structure 10. In some implementations, the first semiconductor layer 12 may be formed on the uppermost portion of the first stacked structure 10. For example, the first sacrificial layer 11 may include silicon germanium (SiGe). For example, the first semiconductor layer 12 may include silicon (Si). Subsequently, the isolation material layer 20 may be formed on the upper surface of the first stacked structure 10. The isolation material layer 20 may include silicon germanium (SiGe).

Subsequently, the second stacked structure 30 may be formed on the upper surface of the isolation material layer 20. The second stacked structure 30 may include second sacrificial layers 31 and second semiconductor layers 32 alternately stacked on the upper surface of the isolation material layer 20. For example, the second sacrificial layer 31 may be formed on a lowermost portion of the second stacked structure 30, and a second semiconductor layer 32 may be formed on an uppermost portion of the second stacked structure 30. For example, the second sacrificial layer 31 may include silicon germanium (SiGe). For example, the second semiconductor layer 32 may include silicon (Si). For example, the concentration of germanium (Ge) in the isolation material layer 20 may be greater than the concentration of germanium (Ge) in each of the first sacrificial layer 11 and the second sacrificial layer 31.

Thereafter, respective portions of the first stacked structure 10, the isolation material layer 20, and the second stacked structure 30 may be etched. While respective portions of the first stacked structure 10, the isolation material layer 20, and the second stacked structure 30 are being etched, a portion of the substrate 100 may also be etched. Through such an etching process, the active pattern 101 may be defined below the first stacked structure 10. The active pattern 101 may protrude in the vertical direction DR3 from the upper surface of the substrate 100. The active pattern 101 may extend in the first horizontal direction DR1.

Subsequently, the field insulating layer 105 may be formed on the upper surface of the substrate 100. The field insulating layer 105 may surround the sidewalls of the active pattern 101. For example, the upper surface of the active pattern 101 may be formed higher than the upper surface of the field insulating layer 105. Next, a pad oxide layer 40 may be formed to cover the upper surface of the field insulating layer 105, the exposed sidewalls of the active pattern 101, the sidewalls of the first stacked structure 10, the sidewalls of the isolation material layer 20, and the sidewalls and the upper surface of the second stacked structure 30. For example, the pad oxide layer 40 may be conformally formed. The pad oxide layer 40 may include silicon oxide (SiO₂), for example.

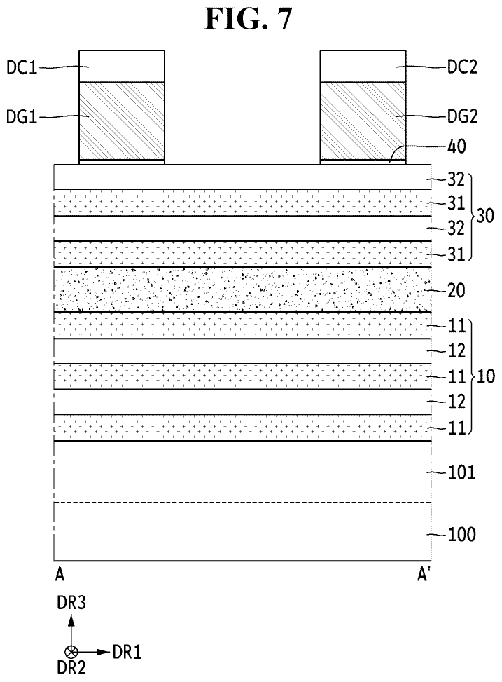

Referring to FIGS. 7 to 9, the first and second dummy gates DG1, DG2 and the first and second dummy capping patterns DC1, DC2, extending in the second horizontal direction DR2, may be formed on the pad oxide layer 40 over the second stacked structure 30 and the field insulating layer 105. For example, the second dummy gate DG2 may be spaced apart from the first dummy gate DG1 in the first horizontal direction DR1. The first dummy capping pattern DC1 may be disposed on the first dummy gate DG1, and the second dummy capping pattern DC2 may be disposed on the second dummy gate DG2. While the first and second dummy gates DG1, DG2 and the first and second dummy capping patterns DC1, DC2 are being formed, the remaining pad oxide layer 40 excluding the portions overlapping with each of the first and second dummy gates DG1, DG2 in the vertical direction DR3 on the substrate 100, may be removed.

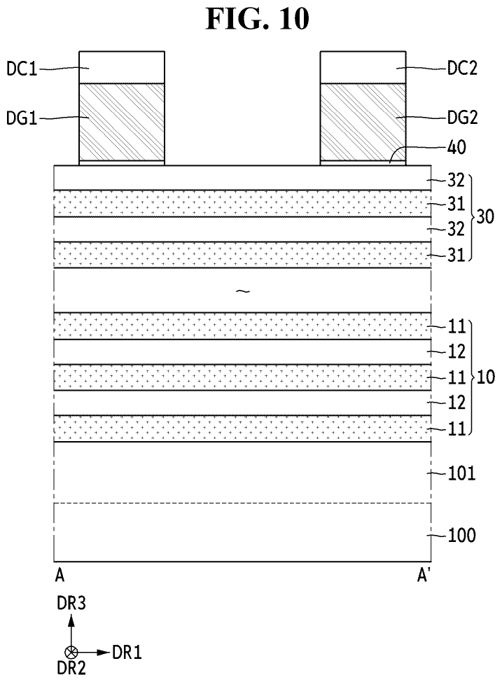

Referring to FIGS. 10 to 12, the isolation material layer 20 (see FIGS. 7 to 9) may be etched. For example, the isolation material layer 20 (see FIGS. 7 to 9) may be etched using a wet etching process.

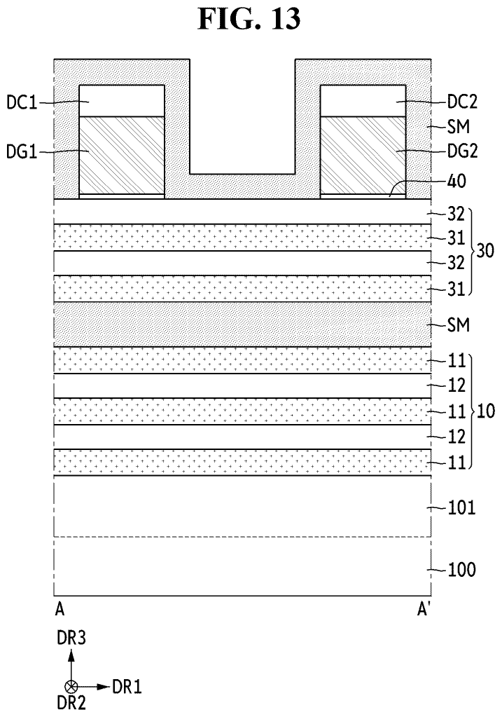

Referring to FIGS. 13 to 15, a spacer material layer SM may be formed to cover the sidewalls of the first and second dummy gates DG1, DG2, the sidewalls and upper surfaces of the first and second dummy capping patterns DC1, DC2, and the upper surfaces of the first stacked structure 10, the second stacked structure 30, and the field insulating layer 105. The spacer material layer SM may fill the portions where the isolation material layer 20 (see FIGS. 7 to 9) has been etched. For example, the spacer material layer SM may be conformally formed. The spacer material layer SM may include any one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), and silicon oxycarbide (SiOC).

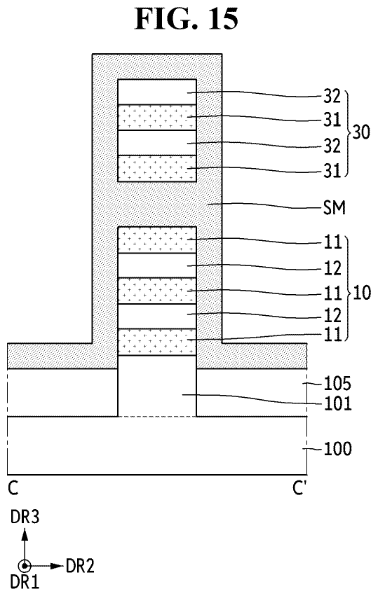

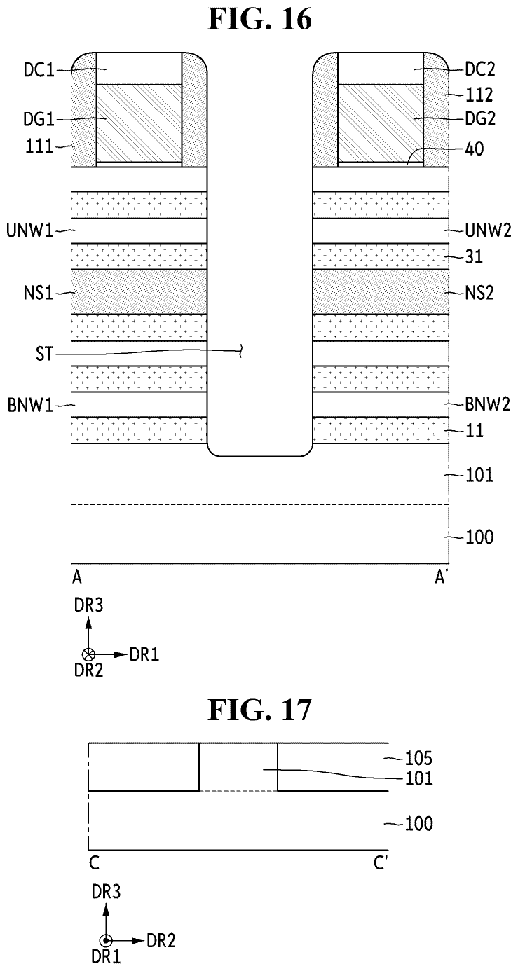

Referring to FIGS. 16 and 17, a source/drain trench ST may be formed by etching each of the first stacked structure 10 (see FIGS. 13 and 15), the spacer material layer SM (see FIGS. 13 and 15), and the second stacked structure 30 (see FIGS. 13 and 15) using first and second dummy gates DG1, DG2 and first and second dummy capping patterns DC1, DC2 as masks. For example, the source/drain trench ST may extend into the interior of the active pattern 101. During the formation of the source/drain trench ST, the spacer material layers SM (see FIG. 13) formed on the upper surfaces of the first and second dummy capping patterns DC1, DC2 may be etched. After the source/drain trench ST is formed, the spacer material layers SM (see FIG. 13) remaining on the sidewall of each of the first and second dummy gates DG1, DG2 and the first and second dummy capping patterns DC1, DC2 may be defined as the first and second gate spacers 111, 112.

For example, after the source/drain trench ST is formed, each of the first semiconductor layer 12 (see FIG. 13) and the second semiconductor layer 32 (see FIG. 13) remaining below the first dummy gate DG1 may be defined as the first plurality of bottom nanosheets BNW1 and the first plurality of upper nanosheets UNW1, respectively. Also, after the source/drain trench ST is formed, each of the first semiconductor layer 12 (see FIG. 13) and the second semiconductor layer 32 (see FIG. 13) remaining below the second dummy gate DG2 may be defined as the second plurality of bottom nanosheets BNW2 and the second plurality of upper nanosheets UNW2, respectively. In addition, after the source/drain trench ST is formed, the spacer material layer SM (see FIG. 13) remaining below the first dummy gate DG1 may be defined as the first nanosheet isolation layer NS1, and the spacer material layer SM (see FIG. 13) remaining below the second dummy gate DG2 may be defined as the second nanosheet isolation layer NS2.

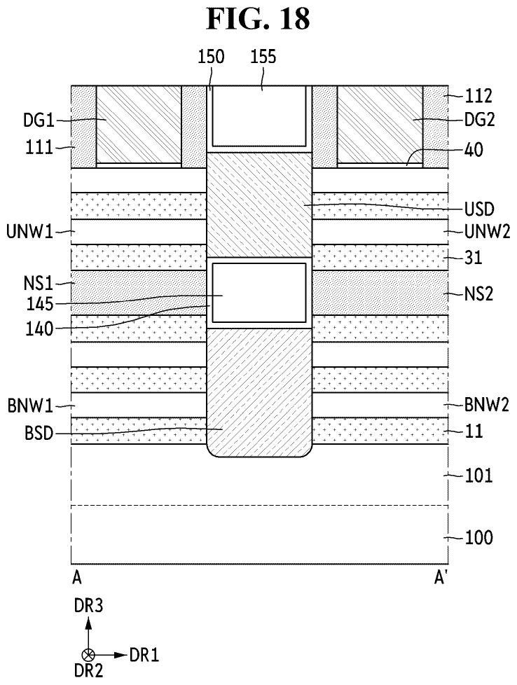

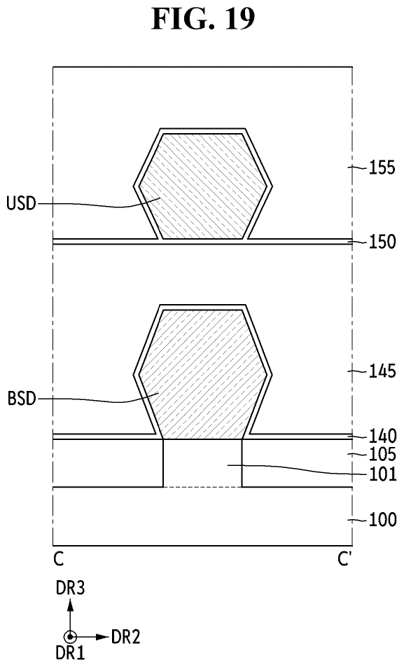

Referring to FIGS. 18 and 19, the bottom source/drain region BSD may be formed within the source/drain trench ST (see FIG. 16). The bottom source/drain region BSD may be in contact with the active pattern 101. In addition, the bottom source/drain region BSD may be in contact with the sidewall of each of the first and second pluralities of bottom nanosheets BNW1, BNW2 in the first horizontal direction DR1. Subsequently, the first etching stop layer 140 may be formed on the upper surface of the field insulating layer 105, on the sidewalls and upper surface of the bottom source/drain region BSD in the second horizontal direction DR2, and on the sidewall of each of the first and second nanosheet isolation layers NS1, NS2 in the second horizontal direction DR2. For example, the first etching stop layer 140 may be formed conformally. Thereafter, the first interlayer insulating layer 145 may be formed on the first etching stop layer 140 to cover the bottom source/drain region BSD. For example, the upper surface of the first interlayer insulating layer 145 may be formed lower than the bottom surface of the lowermost nanosheet of the first plurality of upper nanosheets UNW1.

Subsequently, the upper source/drain region USD may be formed on the upper surface of the first interlayer insulating layer 145 within the source/drain trench ST (see FIG. 16). The upper sauce/drain region USD may be spaced apart from the bottom sauce/drain region BSD in the vertical direction DR3. The upper sauce/drain region USD may be in contact with the sidewall of each of the first and second pluralities of upper nanosheets UNW1, UNW2 in the first horizontal direction DR1. Next, the second etching stop layer 150 may be formed on the upper surface of the first interlayer insulating layer 145, the exposed surface of the upper source/drain region USD, the sidewall of each of the first and second gate spacers 111, 112 in the second horizontal direction DR2, and the upper surface of each of the first and second dummy capping patterns DC1, DC2. For example, the second etching stop layer 150 may be formed conformally. Subsequently, a planarization process may be performed to expose the upper surfaces of the first and second dummy gates DG1, DG2.

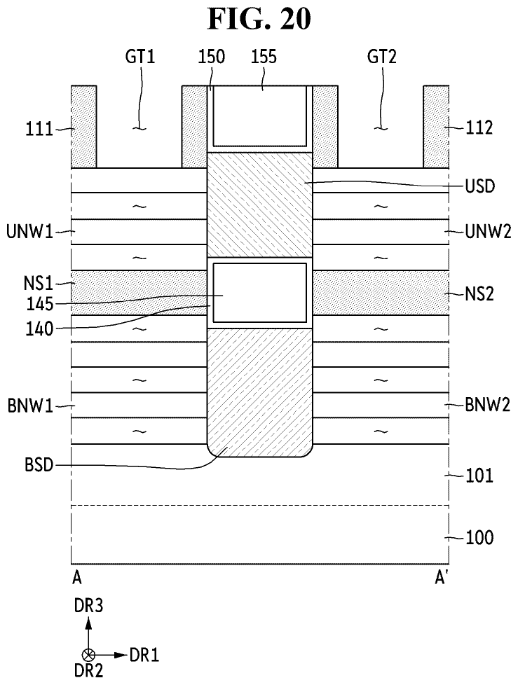

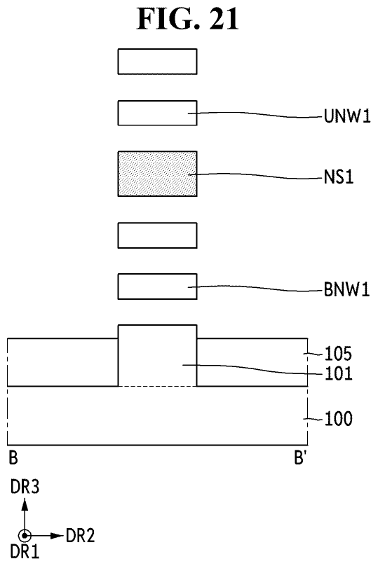

Referring to FIGS. 20 and 21, each of the first and second dummy gates DG1, DG2 (see FIG. 18), the pad oxide layer 40 (see FIG. 18), the first sacrificial layer 11 (see FIG. 18), and the second sacrificial layer 31 (see FIG. 18) may be etched. The portions where each of the first dummy gate DG1 (see FIG. 18), the pad oxide layer 40 (see FIG. 18), the first sacrificial layer 11 (see FIG. 18), and the second sacrificial layer 31 (see FIG. 18) are etched may be defined as a first gate trench GT1. In addition, the portions where the second dummy gate DG2 (see FIG. 18), the pad oxide layer 40 (see FIG. 18), the first sacrificial layer 11 (see FIG. 18), and the second sacrificial layer 31 (see FIG. 18) are etched may be defined as a second gate trench GT2.

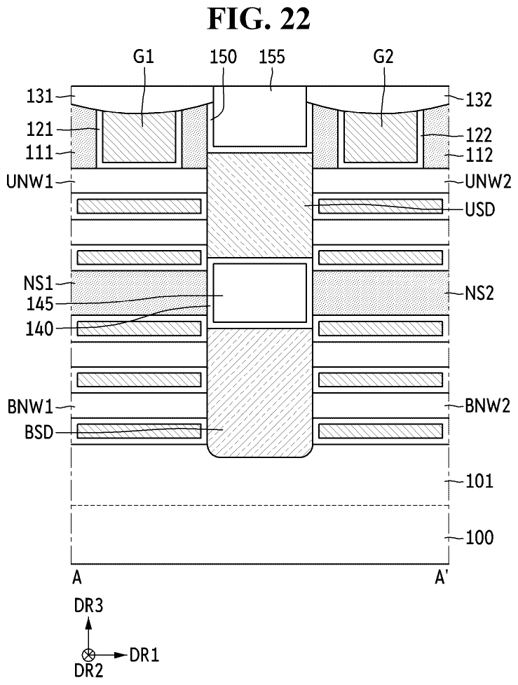

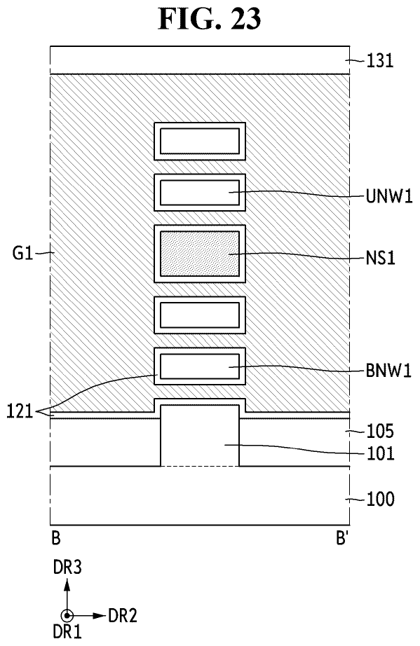

Referring to FIGS. 22 and 23, within the first gate trench GT1 (see FIG. 20), the first gate insulating layer 121, the first gate electrode G1, and the first capping pattern 131 may be sequentially formed. In addition, within the second gate trench GT2 (see FIG. 20), the second gate insulating layer 122, the second gate electrode G2, and the second capping pattern 132 may be sequentially formed. For example, the first gate electrode G1 may surround each of the first plurality of bottom nanosheets BNW1, the first nanosheet isolation layer NS1, and the first plurality of upper nanosheets UNW1. The second gate electrode G2 may surround each of the second plurality of bottom nanosheets BNW2, the second nanosheet isolation layer NS2, and the second plurality of upper nanosheets UNW2.

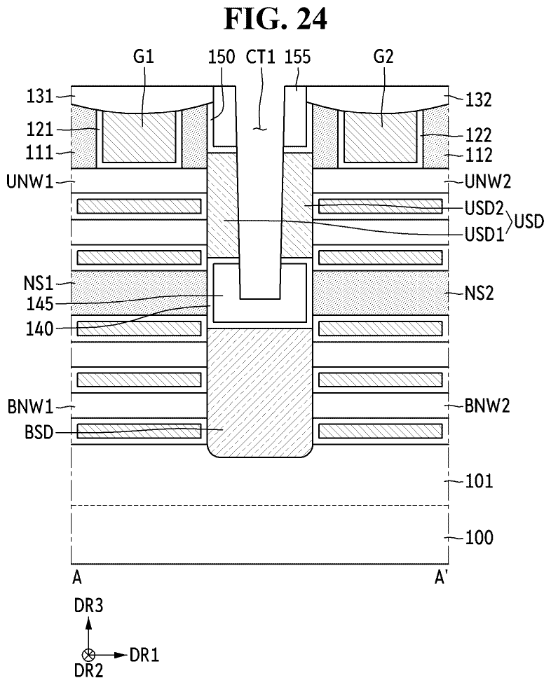

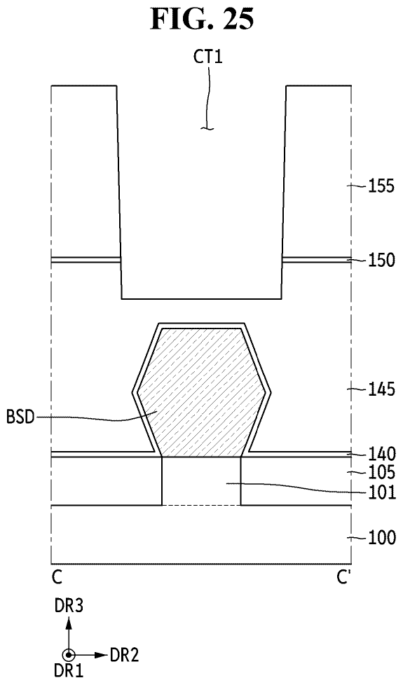

Referring to FIGS. 24 and 25, a first contact trench CT1 may be formed between the first gate electrode G1 and the second gate electrode G2. The first contact trench CT1 may penetrate the second interlayer insulating layer 155, the second etching stop layer 150, and the upper source/drain region USD in the vertical direction DR3 to extend into the interior of the first interlayer insulating layer 145. For example, a bottom surface of the first contact trench CT1 may be formed higher than a bottom surface of the first nanosheet isolation layer NS1. In addition, the bottom surface of the first contact trench CT1 may be formed lower than an upper surface of the first nano sheet isolation layer NS1. For example, the first contact trench CT1 may separate the upper source/drain region USD in the first horizontal direction DR1.

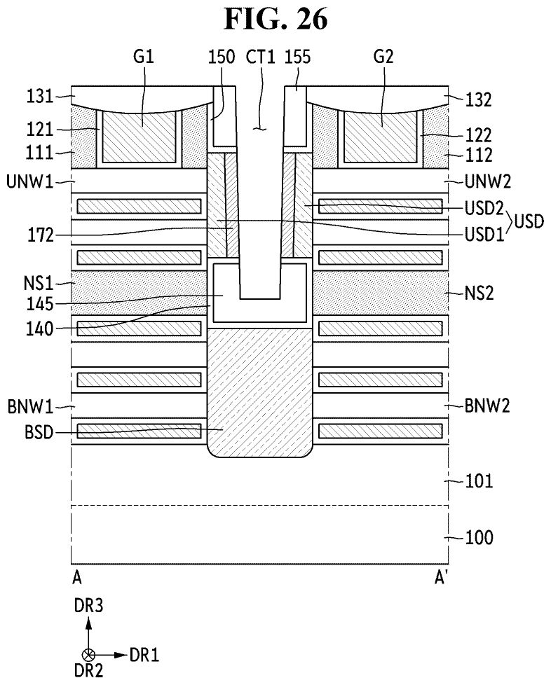

Referring to FIG. 26, the second layer 172 may be formed within the upper source/drain region USD exposed through the first contact trench CT1. For example, the second layer 172 may include a second metal silicide. The second layer 172 may extend from the bottom surface of the upper source/drain region USD to the upper surface of the upper source/drain region USD.

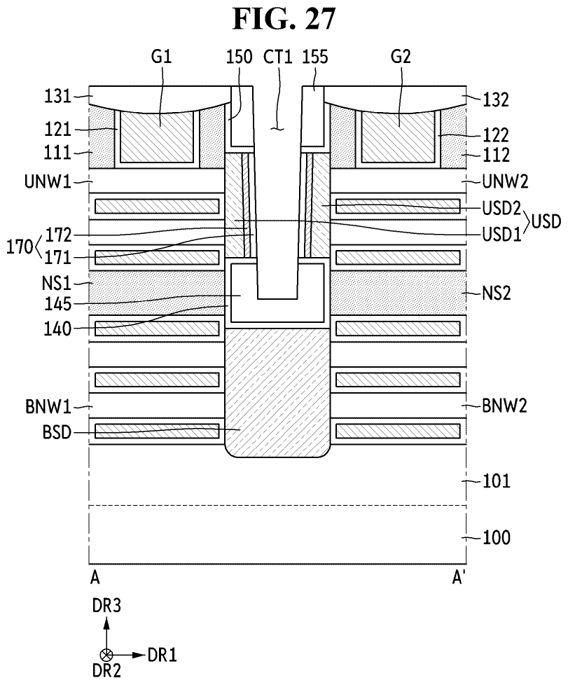

Referring to FIG. 27, a portion of the second layer 172 exposed through the first contact trench CT1 may be nitrided to form the first layer 171. For example, the first layer 171 may extend from the bottom surface of the upper source/drain region USD to the upper surface of the upper source/drain region USD. As a result, the upper silicide layer 170 including the first layer 171 and the second layer 172 may be formed.

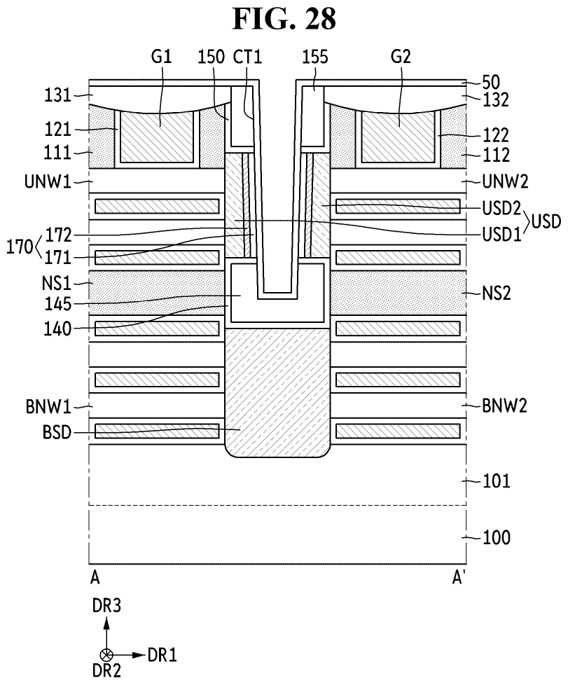

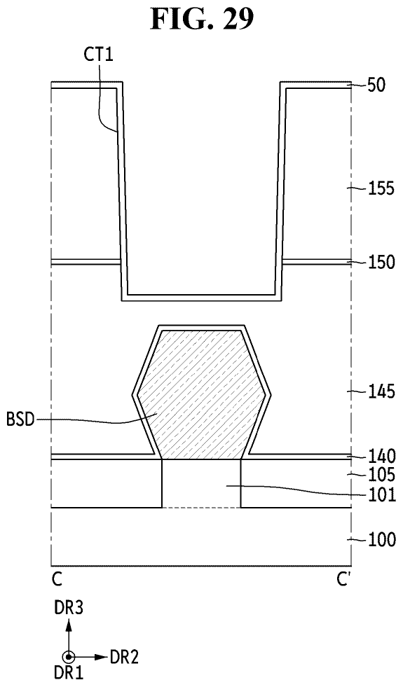

Referring to FIGS. 28 and 29, a liner layer 50 may be formed along the sidewalls and the bottom surface of the first contact trench CT1. For example, the liner layer 50 may also be formed on the upper surfaces of the second isolation layer 155 and each of the first and second capping patterns 131, 132. For example, the liner layer 50 may be formed conformally. For example, the liner layer 50 may include at least one of silicon nitride (SiN), silicon oxycarbonitride (SiOCN), silicon boron carbonitride (SiBCN), silicon carbonitride (SiCN), silicon oxynitride (SiON), or combinations thereof.

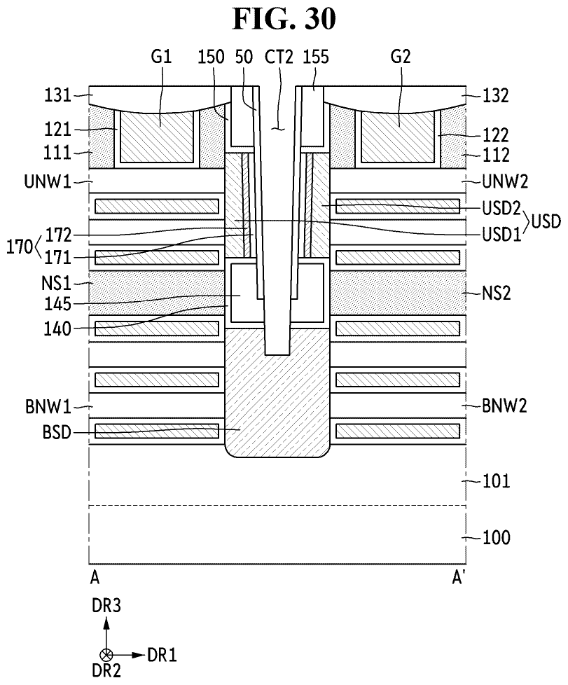

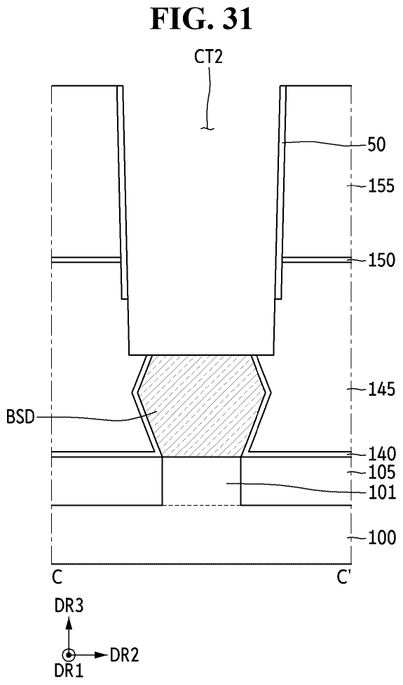

Referring to FIGS. 30 and 31, within the first contact trench CT1 (see FIG. 28 and 29), a second contact trench CT2, which may penetrate the upper source/drain region USD in the vertical direction DR3 and extend at least partially into the interior of the bottom source/drain region BSD, may be formed. For example, the second contact trench CT2, which may penetrate the liner layer 50 formed on the bottom surface of the first contact trench CT1 (see FIGS. 28 and 29), the first interlayer insulating layer 145, and the first etching stop layer 140 in the vertical direction DR3 and extend at least partially into the interior of the bottom source/drain region BSD, may be formed. During the formation of the second contact trench CT2, the liner layer 50 formed on the upper surfaces of the second interlayer insulating layer 155 and each of the first and second capping patterns 131,132 may be etched.

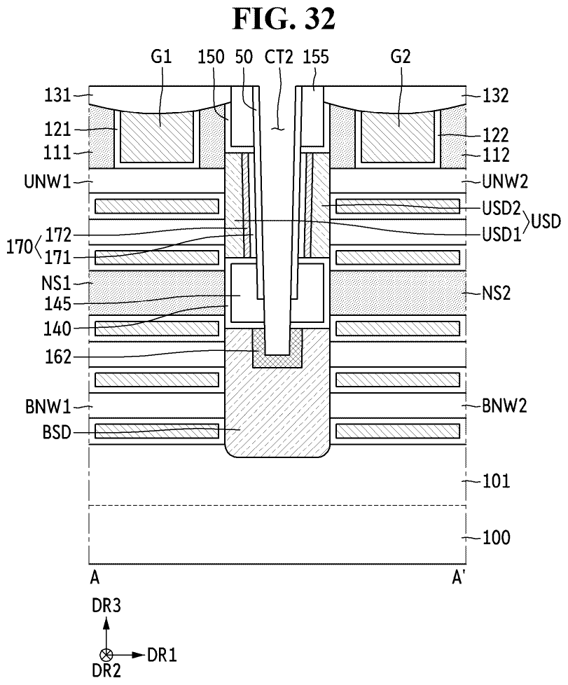

Referring to FIG. 32, the second layer 162 may be formed within the bottom source/drain region BSD exposed through the second contact trench CT2. For example, the second layer 162 may include the first metal silicide.

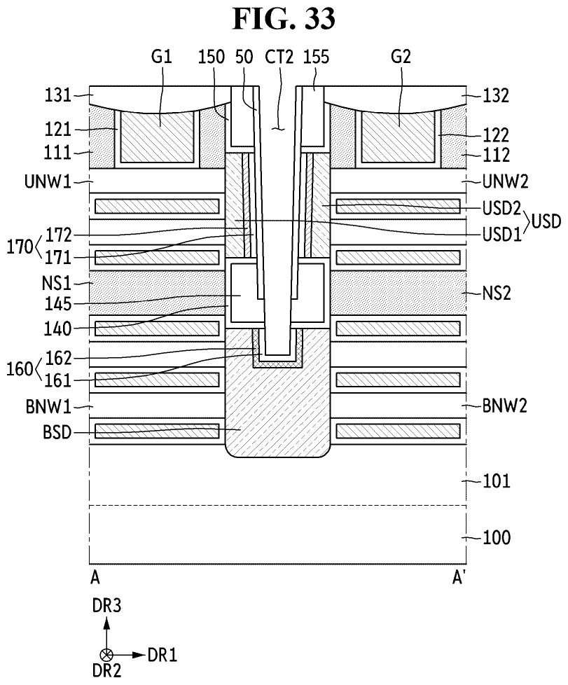

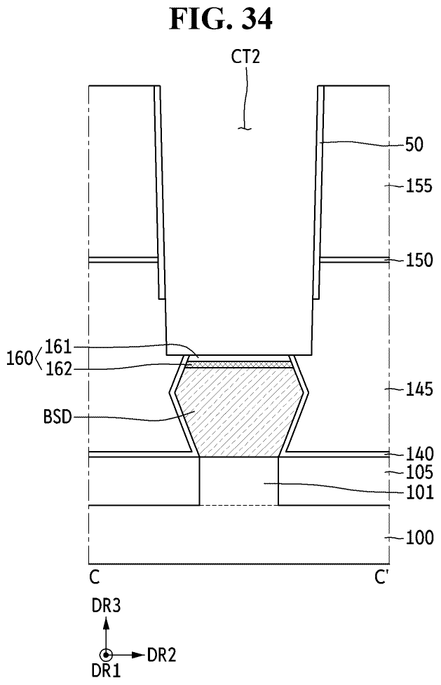

Referring to FIGS. 33 and 34, a portion of the second layer 162 exposed through the second contact trench CT2 may be nitrided to form the first layer 161. As a result, the lower silicide layer 160 including the first layer 161 and the second layer 162 may be formed.

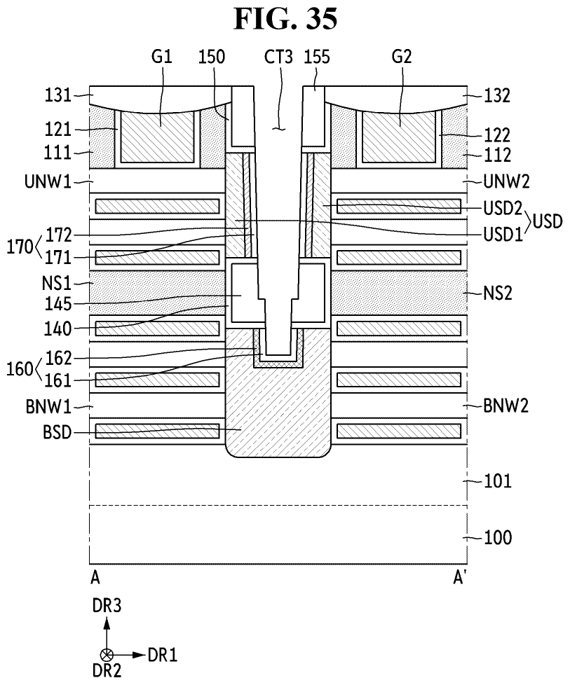

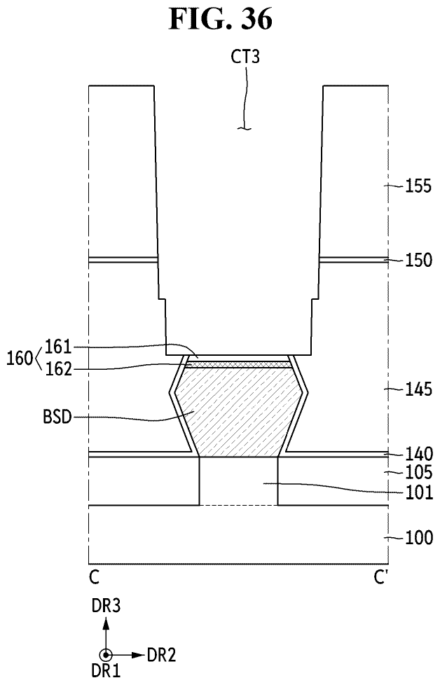

Referring to FIGS. 35 and 36, a third contact trench CT3 may be formed by removing the liner layer 50 (see FIGS. 33 and 34) to expose the upper silicide layer 170 and the lower silicide layer 160.

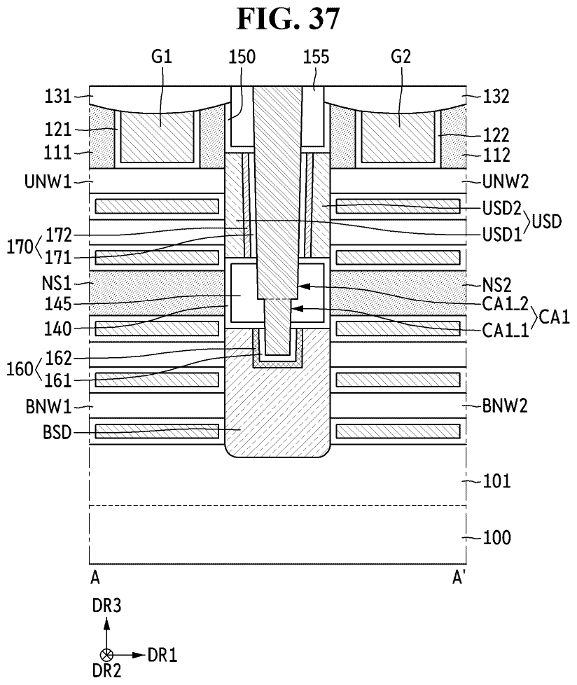

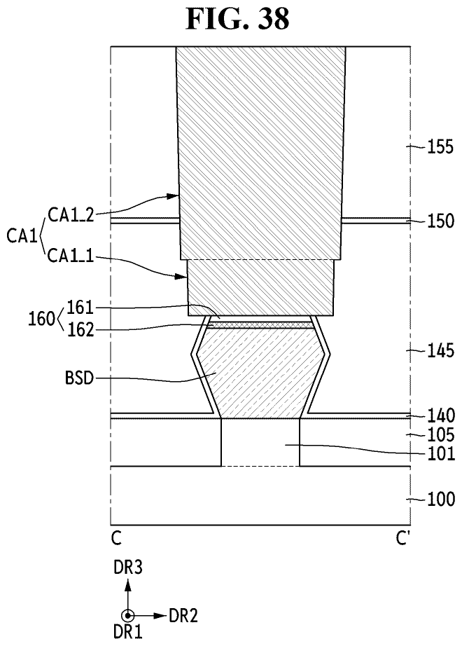

Referring to FIGS. 37 and 38, the source/drain contact CA1 may be formed within the third contact trench CT3 (see FIGS. 35 and 36). For example, the source/drain contact CA1 may fill the interior of the third contact trench CT3 (see FIGS. 35 and 36). For example, the source/drain contact CA1 may be in contact with each of the upper silicide layer 170 and the lower silicide layer 160. For example, the upper surface of the source/drain contact CA1 may be formed on the same plane as the upper surface of the second interlayer insulating layer 155.

Referring to FIGS. 2 to 4, the third etching stop layer 180 and the third interlayer insulating layer 185 may be sequentially formed on the upper surface of each of the first capping pattern 131, the second capping pattern 132, the second interlayer insulating layer 155, the source/drain contact CA1, and the gate contact CB. Subsequently, the first via V1, which may penetrate the third etching stop layer 180 and the third interlayer insulating layer 185 in the vertical direction DR3 and be connected to the source/drain contact CA1, may be formed. Additionally, the second via V2, which may penetrate the third etching stop layer 180 and the third interlayer insulating layer 185 in the vertical direction DR3 and be connected to the gate contact CB, be formed. Through this fabrication process, the semiconductor device shown in FIGS. 2 to 4 may be fabricated.

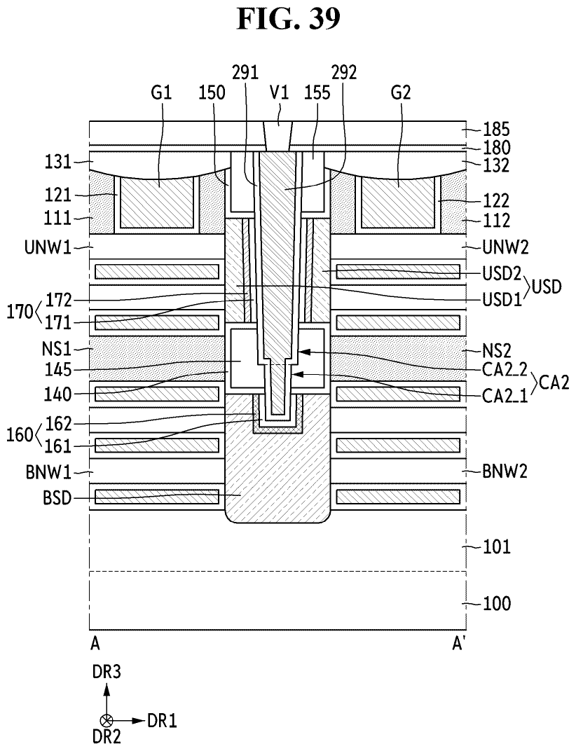

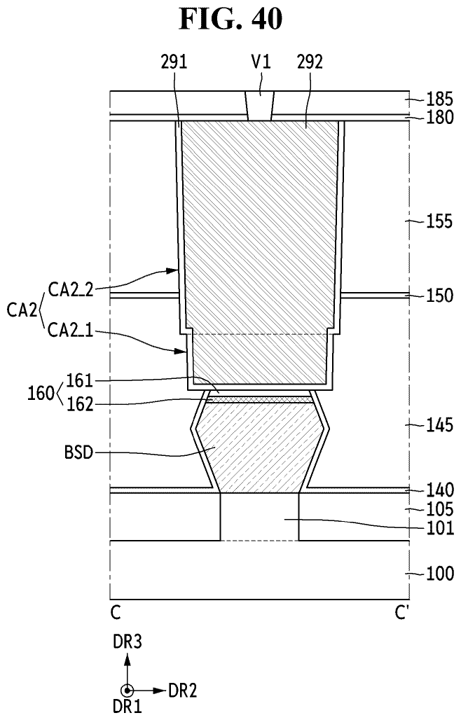

Hereinafter, a semiconductor device according to some implementations of the present disclosure will be described with reference to FIGS. 39 and 40. The description will focus on the differences from the semiconductor device shown in FIGS. 1 to 4.

FIGS. 39 and 40 are cross-sectional views for explaining a semiconductor device according to some implementations of the present disclosure.

Referring to FIGS. 38 and 40, the semiconductor device according to some implementations of the present disclosure may include the source/drain contact CA2 that includes a contact barrier layer 291 and a contact filling layer 292.

For example, the contact barrier layer 291 may form the sidewalls and bottom surface of the first portion CA2_1 of the source/drain contact CA2. Additionally, the contact barrier layer 291 may form the sidewalls of the second portion CA2_2 of the source/drain contact CA2. For example, the contact barrier layer 291 may be formed conformally. For example, the contact filling layer 292 may fill the space between portions of the contact barrier layer 291. For example, an uppermost surface of the contact barrier layer 291 and an upper surface of the contact filling layer 292 may each be formed on the same plane as the upper surface of the second interlayer insulating layer 155.

For example, the contact barrier layer 291 may include any one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), and rhodium (Rh). The contact filling layer 292 may include any one of aluminum (Al), tungsten (W), cobalt (Co), ruthenium (Ru), and molybdenum (Mo).

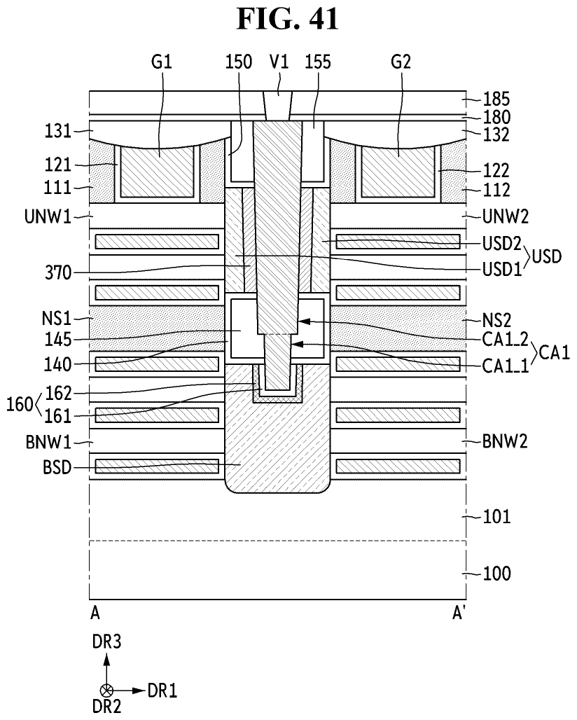

Hereinafter, a semiconductor device according to some implementations of the present disclosure will be described with reference to FIG. 41. The description will focus on the differences from the semiconductor device shown in FIG. 1 to FIG. 4.

FIG. 41 is a cross-sectional view for explaining a semiconductor device according to some implementations of the present disclosure.

Referring to FIG. 41, in the semiconductor device according to some implementations of the present disclosure, the upper silicide layer 370 may be formed as a single layer.

For example, the upper silicide layer 370 may be formed as a single layer including a second metal silicide. For example, the second metal silicide may include any one of molybdenum silicide (SiMo), antimony silicide (SiSb), ruthenium silicide (SiRu), or platinum silicide (SiPt). For example, the upper silicide layer 370 may be in contact with each of the upper source/drain region USD and the source/drain contact CA1.

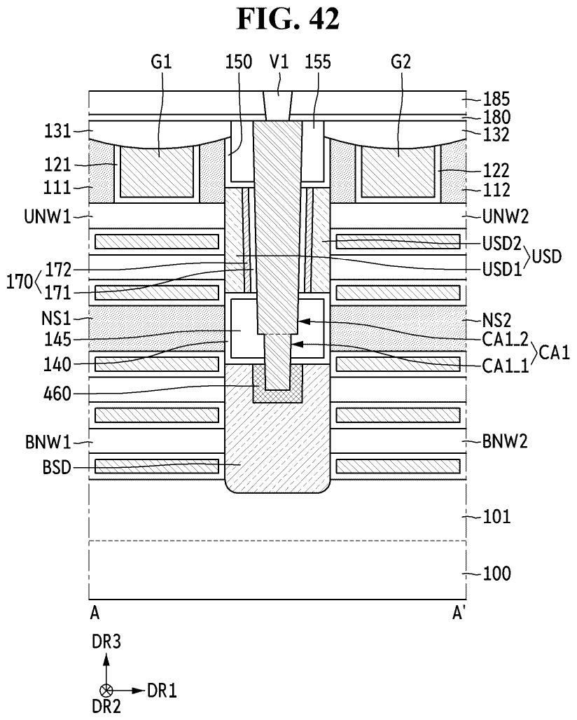

Hereinafter, a semiconductor device according to some implementations of the present disclosure will be described with reference to FIG. 42. The description will focus on the differences from the semiconductor device shown in FIG. 1 to FIG. 4.

FIG. 42 is a cross-sectional view for explaining a semiconductor device according to some implementations of the present disclosure.

Referring to FIG. 42, in the semiconductor device according to some implementations of the present disclosure, the lower silicide layer 460 may be formed as a single layer.

For example, the lower silicide layer 460 may be formed as a single layer including a first metal silicide. The first metal silicide may include any one of scandium silicide (SiSc), erbium silicide (SiEr), lanthanum silicide (SiLa), yttrium silicide (SiY), hafnium silicide (SiHf), or zirconium silicide (SiZr). For example, the lower silicide layer 460 may be in contact with each of the bottom source/drain region BSD and the source/drain contact CA1.

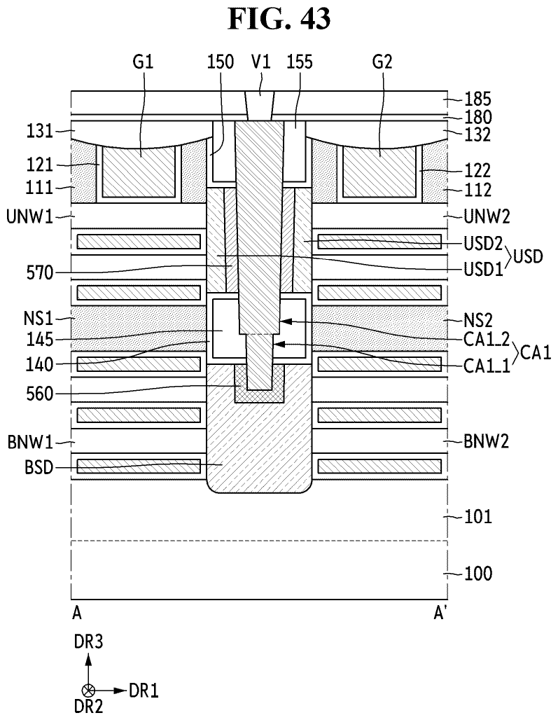

Hereinafter, a semiconductor device according to some implementations of the present disclosure will be described with reference to FIG. 43. The description will focus on the differences from the semiconductor device shown in FIGS. 1 to 4.

FIG. 43 is a cross-sectional view for explaining a semiconductor device according to some implementations of the present disclosure.

Referring to FIG. 43, in the semiconductor device according to some implementations of the present disclosure, the lower silicide layer 560 and the upper silicide layer 570 may each be formed as a single layer.

For example, the lower silicide layer 560 may be formed as a single layer including a first metal silicide. Additionally, the upper silicide layer 570 may be formed as a single layer including a second metal silicide. For example, the lower silicide layer 560 may be in contact with each of the bottom source/drain region BSD and the source/drain contact CA1. The upper silicide layer 570 may be in contact with each of the upper source/drain region USD and the source/drain contact CA1.

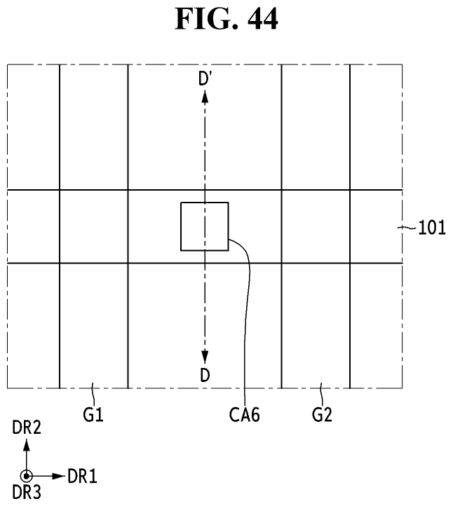

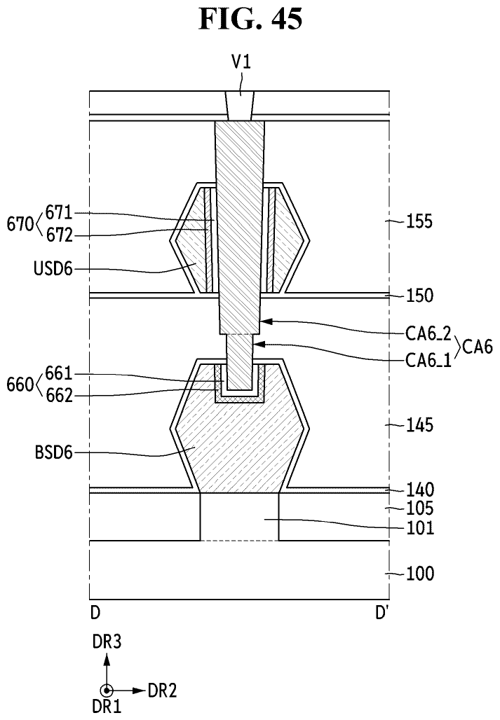

Hereinafter, a semiconductor device according to some implementations of the present disclosure will be described with reference to FIGS. 44 and 45. The description will focus on the differences from the semiconductor device shown in FIGS. 1 to 4.

FIG. 44 is a schematic layout diagram for explaining a semiconductor device according to some implementations of the present disclosure. FIG. 45 is a cross-sectional view taken along line D-D′ of FIG. 44.

Referring to FIGS. 44 and 45, in the semiconductor device according to some implementations of the present disclosure, the source/drain contact CA6 may be formed in a hole shape.

For example, the upper source/drain region USD6 may be disposed on both sidewalls of the source/drain contact CA6 in the second horizontal direction DR2. For example, the width of the source/drain contact CA6 in the second horizontal direction DR2 may be smaller than the width of the upper source/drain region USD6 in the second horizontal direction DR2. For example, the width of the source/drain contact CA6 in the second horizontal direction DR2 may be smaller than the width of the active pattern 101 in the second horizontal direction DR2.

For example, the lower silicide layer 660 may be disposed between both sidewalls of the first portion CA6_1 of the source/drain contact CA6 in the second horizontal direction DR2 and the bottom source/drain region BSD6. Additionally, the lower silicide layer 660 may be disposed between the bottom surface of the first portion CA6_1 of the source/drain contact CA6 and the bottom source/drain region BSD6. The lower silicide layer 660 may include the first layer 661 being in contact with the first portion CA6_1 of the source/drain contact CA6 and the second layer 662 being in contact with the bottom source/drain region BSD6. For example, the second layer 662 of the lower silicide layer 660 may include a first metal silicide. The first layer 661 of the lower silicide layer 660 may include a nitrided form of the first metal silicide.

For example, the upper silicide layer 670 may be disposed between both sidewalls of a second portion CA6_2 of the source/drain contact CA6 in the second horizontal direction DR2 and the upper source/drain region USD6. The upper silicide layer 670 may include a first layer 671 being in contact with the second portion CA6_2 of the source/drain contact CA6 and a second layer 672 being in contact with the upper source/drain USD6. For example, the second layer 672 of the upper silicide layer 670 may include a second metal silicide. The first layer 671 of the upper silicide layer 670 may include a nitrided form of the second metal silicide.

According to some implementations of the present disclosure, there is provided a method for fabricating a semiconductor device, including forming an active pattern extending in a first horizontal direction on an upper surface of a substrate, forming a plurality of bottom nanosheets, a nanosheet isolation layer and a plurality of upper nanosheets that are spaced apart from each other in a vertical direction and stacked on an upper surface of the active pattern, forming a bottom source/drain region being in contact with sidewalls of the plurality of bottom nanosheets in the first horizontal direction, forming an upper source/drain region being in contact with sidewalls of the plurality of upper nanosheets in the first horizontal direction, the upper source/drain region spaced apart from an upper surface of the bottom source/drain region in the vertical direction, forming a first contact trench penetrating the upper source/drain region in the vertical direction, forming an upper silicide layer in the upper source/drain region exposed through the first contact trench, forming a second contact trench penetrating the upper source/drain region in the vertical direction in the first contact trench, at least a portion of the second contact trench extending into the bottom source/drain region, forming a lower silicide layer in the bottom source/drain region exposed through the second contact trench, and forming a source/drain contact being in contact with each of the upper silicide layer and the lower silicide layer, where the lower silicide layer includes a first metal silicide, and the upper silicide layer includes a second metal silicide different from the first metal silicide.

According to some implementations of the present disclosure, there is provided a method for fabricating a semiconductor device, where forming the second contact trench includes forming a liner layer along sidewalls and a bottom surface of the first contact trench, and forming the second contact trench by penetrating in the vertical direction the liner layer formed on the bottom surface of the first contact trench, at least a portion of the second contact trench extending into the bottom source/drain region.

According to some implementations of the present disclosure, there is provided a method for fabricating a semiconductor device, where forming the source/drain contact includes forming a third contact trench by removing the liner layer after forming the lower silicide layer, the third contact trench exposing each of the upper silicide layer and the lower silicide layer, and forming the source/drain contact filling in the third contact trench.

According to some implementations of the present disclosure, there is provided a method for fabricating a semiconductor device, where the lower silicide layer includes a first layer being in contact with the source/drain contact, the first layer including a nitrided form of the first metal silicide, and a second layer being in contact with the lower source/drain region, the second layer including the first metal silicide.

According to some implementations of the present disclosure, there is provided a method for fabricating a semiconductor device, where forming the lower silicide layer includes forming the second layer in the bottom source/drain region exposed through the second contact trench, and forming the first layer by nitriding a portion of the second layer exposed through the second contact trench.

According to some implementations of the present disclosure, there is provided a method for fabricating a semiconductor device, where the upper silicide layer includes a first layer being in contact with the source/drain contact, the first layer including a nitrided form of the second metal silicide, and a second layer being in contact with the upper source/drain region, the second layer including the second metal silicide.

According to some implementations of the present disclosure, there is provided a method for fabricating a semiconductor device, where forming the upper silicide layer includes forming the second layer in the upper source/drain region exposed through the first contact trench, and forming the first layer by nitriding a portion of the second layer exposed through the first contact trench.

Although the implementations of the present disclosure have been described above with reference to the accompanying drawings, it will be understood that the present disclosure is not limited to these implementations and may be implemented in various other forms. Those skilled in the art to which the present disclosure pertains will recognize that it can be implemented in other specific forms without departing from its technical concept or essential features. Accordingly, the above-described implementations should be understood as illustrative rather than restrictive in all respects.

What is claimed is:

1. A semiconductor device comprising:
a substrate;
an active pattern extending in a first horizontal direction on an upper surface of the substrate;
a gate electrode extending, in a second horizontal direction that is different from the first horizontal direction, on the active pattern;
a bottom source/drain region on a first side of the gate electrode and on the active pattern;
an upper source/drain region on the first side of the gate electrode, the upper source/drain region being spaced apart from the bottom source/drain region in a vertical direction;
an interlayer insulating layer covering at least a portion of the upper source/drain region;
a source/drain contact on the first side of the gate electrode, the source/drain contact extending into the interlayer insulating layer and the upper source/drain region in the vertical direction, wherein at least a portion of the source/drain contact extends into the bottom source/drain region and the source/drain contact is connected to each of the bottom source/drain region and the upper source/drain region;
a lower silicide layer between the bottom source/drain region and the source/drain contact, the lower silicide layer comprising a first metal silicide; and
an upper silicide layer between the upper source/drain region and the source/drain contact, the upper silicide layer comprising a second metal silicide that is different from the first metal silicide.

2. The semiconductor device of claim 1, comprising:
a plurality of bottom nanosheets spaced apart from each other in the vertical direction on the active pattern, the plurality of bottom nanosheets being in contact with a sidewall of the bottom source/drain region in the first horizontal direction;
a nanosheet isolation layer on the plurality of bottom nanosheets, the nanosheet isolation layer comprising an insulating material; and
a plurality of upper nanosheets spaced apart from each other in the vertical direction on the nanosheet isolation layer, the plurality of upper nanosheets being in contact with a sidewall of the upper source/drain region in the first horizontal direction,
wherein the gate electrode surrounds each of the plurality of bottom nanosheets, the nanosheet isolation layer, and the plurality of upper nanosheets.

3. The semiconductor device of claim 1, wherein an upper surface of the source/drain contact is on a same plane as an upper surface of the interlayer insulating layer.

4. The semiconductor device of claim 1, wherein a bottom surface of the source/drain contact is positioned higher than a bottom surface of the bottom source/drain region.

5. The semiconductor device of claim 1, wherein the source/drain contact comprises:
a first portion extending at least partially into the bottom source/drain region, an upper surface of the first portion being positioned higher than an upper surface of the bottom source/drain region; and
a second portion having a bottom surface in contact with the upper surface of the first portion, the second portion extending into the interlayer insulating layer and the upper source/drain region in the vertical direction, and
wherein a width of the upper surface of the first portion of the source/drain contact in the first horizontal direction is less than a width of the bottom surface of the second portion of the source/drain contact in the first horizontal direction.

6. The semiconductor device of claim 5, wherein a width of the upper surface of the first portion of the source/drain contact in the second horizontal direction is less than a width of the bottom surface of the second portion of the source/drain contact in the second horizontal direction.

7. The semiconductor device of claim 1, wherein a bottom surface of the upper silicide layer is on a same plane as a bottom surface of the upper source/drain region, and
wherein an upper surface of the upper silicide layer is on a same plane as an upper surface of the upper source/drain region.

8. The semiconductor device of claim 1, wherein the upper source/drain region is separated into a first region and a second region in the first horizontal direction, based on the source/drain contact being therebetween.

9. The semiconductor device of claim 1, wherein the lower silicide layer comprises:
a first layer in contact with the source/drain contact, the first layer comprising a nitrided form of the first metal silicide; and
a second layer in contact with the bottom source/drain region, the second layer comprising the first metal silicide.

10. The semiconductor device of claim 1, wherein the upper silicide layer comprises:
a first layer in contact with the source/drain contact, the first layer comprising a nitrided form of the second metal silicide; and
a second layer in contact with the upper source/drain region, the second layer comprising the second metal silicide.

11. The semiconductor device of claim 1, wherein the source/drain contact comprises:
a contact barrier layer defining sidewalls and a bottom surface of the source/drain contact; and
a contact filling layer filling a space defined by the sidewalls and the bottom surface of the source/drain contact.

12. The semiconductor device of claim 1, wherein the upper source/drain region is at a first sidewall and a second sidewall of the sidewalls of the source/drain contact in the second horizontal direction.

13. A semiconductor device comprising:
a substrate;
an active pattern extending in a first horizontal direction on an upper surface of the substrate;
a plurality of bottom nanosheets spaced apart from each other in a vertical direction and stacked on the active pattern;
a nanosheet isolation layer on the plurality of bottom nanosheets, the nanosheet isolation layer comprising an insulating material;
a plurality of upper nanosheets spaced apart from each other in the vertical direction and stacked on an upper surface of the nanosheet isolation layer;
a bottom source/drain region in contact with sidewalls of the plurality of bottom nanosheets in the first horizontal direction;
an upper source/drain region spaced apart from the bottom source/drain region in the vertical direction, the upper source/drain region being in contact with sidewalls of the plurality of upper nanosheets in the first horizontal direction;
a source/drain contact penetrating the upper source/drain region in the vertical direction, wherein at least a portion of the source/drain contact extends into the bottom source/drain region and the source/drain contact is connected to each of the bottom source/drain region and the upper source/drain region;
a lower silicide layer between the bottom source/drain region and the source/drain contact, the lower silicide layer comprising a first metal silicide; and
an upper silicide layer between the upper source/drain region and the source/drain contact, the upper silicide layer comprising a second metal silicide that is different from the first metal silicide.

14. The semiconductor device of claim 13, comprising:
a gate electrode extending in a second horizontal direction that is different from the first horizontal direction on the active pattern, the gate electrode surrounding each of the plurality of bottom nanosheets, the nanosheet isolation layer, and the plurality of upper nanosheets.

15. The semiconductor device of claim 13, wherein a width of an upper surface of the source/drain contact in the first horizontal direction is greater than a width of a bottom surface of the source/drain contact in the first horizontal direction.

16. The semiconductor device of claim 13, wherein the upper source/drain region is separated into a first region and a second region in the first horizontal direction, based on the source/drain contact being therebetween.

17. The semiconductor device of claim 13, wherein the lower silicide layer comprises:
a first layer in contact with the source/drain contact, the first layer comprising a nitrided form of the first metal silicide; and
a second layer in contact with the bottom source/drain region, the second layer comprising the first metal silicide.

18. The semiconductor device of claim 13, wherein the upper silicide layer comprises:
a first layer in contact with the source/drain contact, the first layer comprising a nitrided form of the second metal silicide; and
a second layer in contact with the upper source/drain region, the second layer comprising the second metal silicide.

19. The semiconductor device of claim 13, wherein the lower silicide layer is a single layer comprising the first metal silicide, and
wherein the upper silicide layer is a single layer comprising the second metal silicide.

20. A semiconductor device comprising:
a substrate;
an active pattern extending in a first horizontal direction on an upper surface of the substrate;
a plurality of bottom nanosheets spaced apart from each other in a vertical direction and stacked on the active pattern;
a nanosheet isolation layer on the plurality of bottom nanosheets, the nanosheet isolation layer comprising an insulating material;
a plurality of upper nanosheets spaced apart from each other in the vertical direction and stacked on an upper surface of the nanosheet isolation layer;
a gate electrode extending, in a second horizontal direction that is different from the first horizontal direction, on the active pattern, the gate electrode surrounding each of the plurality of bottom nanosheets, the nanosheet isolation layer, and the plurality of upper nanosheets;
a bottom source/drain region on a first side of the gate electrode and on the active pattern, the bottom source/drain region being in contact with sidewalls of the plurality of bottom nanosheets in the first horizontal direction;
an upper source/drain region on the first side of the gate electrode, the upper source/drain region being spaced apart from the bottom source/drain region in the vertical direction, the upper source/drain region being in contact with sidewalls of the plurality of upper nanosheets in the first horizontal direction;
a first interlayer insulating layer between the bottom source/drain region and the upper source/drain region;
a second interlayer insulating layer on an upper surface of the upper source/drain region;
a source/drain contact extending into the second interlayer insulating layer, the upper source/drain region, and the first interlayer insulating layer in the vertical direction, wherein at l east a portion of the source/drain contact extends into the bottom source/drain region, wherein the upper source/drain region is separated into a first region and a second region in the first horizontal direction, based on the source/drain contact being therebetween, wherein the source/drain contact is connected to each of the bottom source/drain region and the upper source/drain region, and wherein sidewalls of the source/drain contact have a stepped profile in the first horizontal direction in the first interlayer insulating layer;
a lower silicide layer between the bottom source/drain region and the source/drain contact, the lower silicide layer comprising a first metal silicide; and
an upper silicide layer between the upper source/drain region and the source/drain contact, the upper silicide layer comprising a second metal silicide different from the first metal silicide,
wherein the upper silicide layer comprises:
a first layer in contact with the source/drain contact, the first layer comprising a nitrided form of the second metal silicide, and
a second layer in contact with the upper source/drain region, the second layer comprising the second metal silicide.
